(19) United States
(12) Patent Application Publication
(10) Pub. No.: US 2023/0010535 A1
(43) Pub. Date: Jan. 12, 2023

(54) ELECTROACTIVE COMPOUNDS

(71) Applicant: DUPONT ELECTRONICS, INC., Wilmington, DE (US)

(72) Inventors: Viacheslav V. Diev, Wilmington, DE (US); Denis Yurievich Kondakov, Wilmington, DE (US); Yunlong Zou, Wilmington, DE (US)

(21) Appl. No.: 17/783,009

(22) PCT Filed: Dec. 8, 2020
(86) PCT No.: PCT/US2020/063766

§ 371 Date: Jun. 7, 2022

Related U.S. Application Data
(60) Provisional application No. 62/951,040, filed on Dec. 20, 2019.

(51) Int. Cl. C07F 5/02; H01L 51/50; H01L 51/00

(52) U.S. Cl. CPC C07F 5/027; H01L 51/5012; H01L 51/008; H01L 51/0071

(57) ABSTRACT

There is provided a polycyclic aromatic compound having a single boron-nitrogen bond and including a core structure of Core A, Core B, or Core C

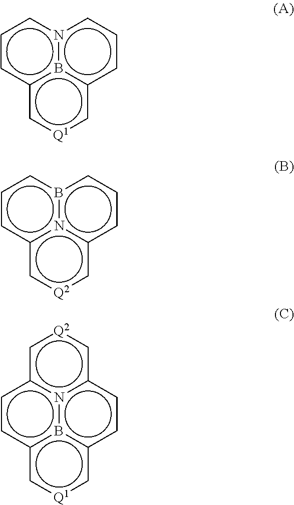

In the formulas:
Q¹ and Q² are the same or different and are a single bond, O, S, NR¹², BR¹², CR¹³R¹⁴, or SiR¹³R¹⁴; and
R¹²-R¹⁴ are the same or different and are alkyl, carbocyclic aryl, heteroaryl, or substituted derivatives thereof.

### CLAIM OF BENEFIT OF PRIOR APPLICATION

This application claims the benefit of U.S. Provisional Application No. 62/951040, filed Dec. 20, 2019, which is incorporated in its entirety herein by reference.

### BACKGROUND INFORMATION

### Field of the Disclosure

This disclosure relates in general to electroactive compounds and their use in electronic devices.

### Description of the Related Art

Organic electronic devices that emit light, such as light-emitting diodes that make up displays, are present in many different kinds of electronic equipment. In all such devices, an organic active layer is sandwiched between two electrical contact layers. At least one of the electrical contact layers is light-transmitting so that light can pass through the electrical contact layer. The organic active layer emits light through the light-transmitting electrical contact layer upon application of electricity across the electrical contact layers.

It is well known to use organic electroluminescent compounds as the active component in light-emitting diodes. Simple organic molecules, such as anthracene, thiadiazole derivatives, and coumarin derivatives are known to show electroluminescence. Metal complexes, particularly iridium and platinum complexes are also known to show electroluminescence. In some cases these small molecule compounds are present as a dopant in a host material to improve processing and/or electronic properties.

There is a continuing need for new electroactive compounds that can be used as hosts or electroluminescent materials.

### SUMMARY

There is provided a polycyclic aromatic compound having a single boron-nitrogen bond and comprising a core structure of Core A, Core B, or Core C

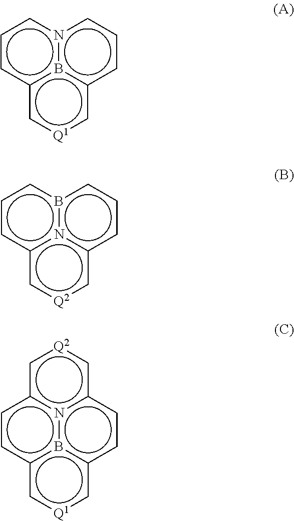

wherein:
Q¹ and Q² are the same or different and are selected from the group consisting of a single bond, O, S, NR¹², BR¹², CR¹³R¹⁴, and SiR¹³R¹⁴; and
R¹²-R¹⁴ are the same or different and are selected from the group consisting of alkyl, carbocyclic aryl, heteroaryl, and substituted derivatives thereof.

There is further provided a compound having Formula I, Formula II, Formula III, Formula IV, Formula V, or Formula VI

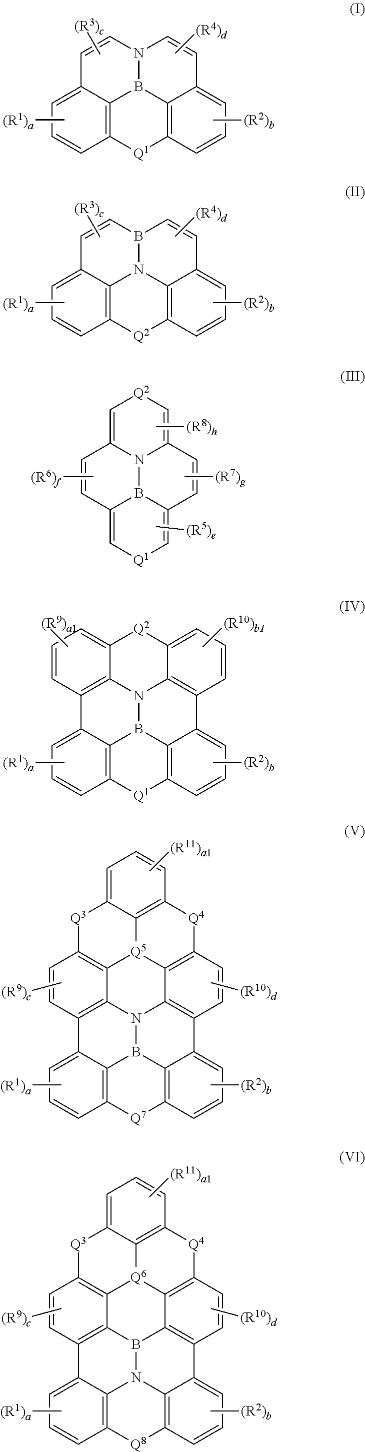

wherein:
Q¹-Q⁴ are the same or different and are selected from the group consisting of a single bond, O, S, NR¹², BR¹², CR¹³R¹⁴, and SiR¹³R¹⁴;
Q⁵ and Q⁶ are the same or different and are selected from the group consisting of N, B, P(O), CR¹³, and SiR¹³;
Q⁷ and Q⁸ are the same or different and are selected from the group consisting no bond, a single bond, O, S, NR¹², BR¹², CR¹³R¹⁴, and SiR¹³R¹⁴;
R¹-R¹¹ are the same or different at each occurrence and are selected from the group consisting of D, F, CN, alkyl, alkoxy, fluoroalkyl, carbocyclic aryl, aryloxy, heteroaryl, diarylamino, silyl, siloxane, siloxy, germyl, deuterated alkyl, deuterated partially-fluorinated alkyl, deuterated alkoxy, deuterated carbocyclic aryl, deuterated aryloxy, deuterated heteroaryl, deuterated diarylamino, deuterated silyl, deuterated siloxane, deuterated siloxy, and deuterated germyl, where adjacent R groups or R groups on adjacent rings can be joined together to form a 5- or 6-membered cycloaliphatic ring, carbocyclic aromatic ring, heteroaromatic ring, or a substituted derivative thereof;

R¹²-R¹⁴ are the same or different and are selected from the group consisting of alkyl, carbocyclic aryl, heteroaryl, and substituted derivatives thereof;
a, a1, b, and b1 are the same or different and are an integer from 0-3; and
c, d, and e-h are the same or different and are an integer from 0-2.

There is further provided a polycyclic aromatic compound having two boron-nitrogen bonds and having Formula VII, Formula VIII, Formula IX, Formula X, or Formula XI

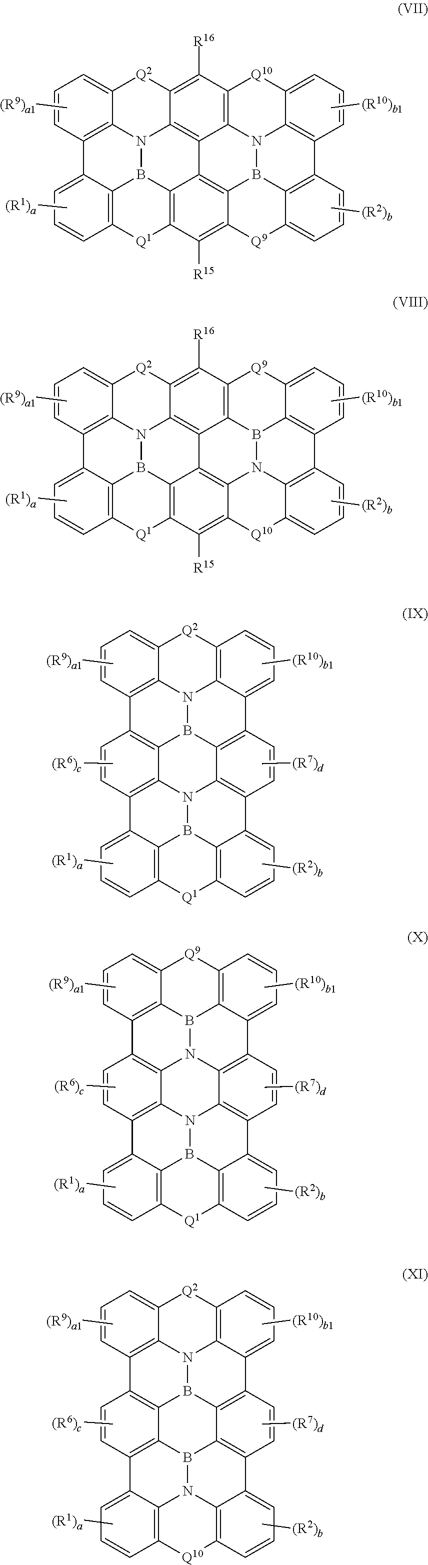

wherein:
Q¹, Q², Q⁹, and Q¹⁰ are the same or different and are selected from the group consisting of a single bond, O, S, NR¹², BR¹², CR¹³R¹⁴, and SiR¹³R¹⁴;
R¹, R², R⁶, R⁷, R⁹, and R¹⁰ are the same or different at each occurrence and are selected from the group consisting of D, F, CN, alkyl, alkoxy, fluoroalkyl, carbocyclic aryl, aryloxy, heteroaryl, diarylamino, silyl, siloxane, siloxy, germyl, deuterated alkyl, deuterated partially-fluorinated alkyl, deuterated alkoxy, deuterated carbocyclic aryl, deuterated aryloxy, deuterated heteroaryl, deuterated diarylamino, deuterated silyl, deuterated siloxane, deuterated siloxy, and deuterated germyl, where adjacent R groups or R groups on adjacent rings can be joined together to form a 5- or 6-membered cycloaliphatic ring, carbocyclic aromatic ring, heteroaromatic ring, or a substituted derivative thereof;
R¹²-R¹⁴ are the same or different and are selected from the group consisting of alkyl, carbocyclic aryl, heteroaryl, and substituted derivatives thereof;
R¹⁵ and R¹⁶ are the same or different at each occurrence and are selected from the group consisting of H, D, F, CN, alkyl, alkoxy, fluoroalkyl, carbocyclic aryl, aryloxy, heteroaryl, diarylamino, silyl, siloxane, siloxy, germyl, deuterated alkyl, deuterated partially-fluorinated alkyl, deuterated alkoxy, deuterated carbocyclic aryl, deuterated aryloxy, deuterated heteroaryl, deuterated diarylamino, deuterated silyl, deuterated siloxane, deuterated siloxy, and deuterated germyl, where adjacent R groups or R groups on adjacent rings can be joined together to form a 5- or 6-membered cycloaliphatic ring, carbocyclic aromatic ring, heteroaromatic ring, or a substituted derivative thereof;
a, a1, b, and b1 are the same or different and are an integer from 0-3; and
c and d are the same or different and are an integer from 0-2.

There is also provided an organic electronic device comprising a first electrical contact, a second electrical contact and a photoactive layer therebetween, the photoactive layer comprising a compound having a core as described above.

The foregoing general description and the following detailed description are exemplary and explanatory only and are not restrictive of the invention, as defined in the appended claims.

### BRIEF DESCRIPTION OF THE DRAWINGS

Embodiments are illustrated in the accompanying figures to improve understanding of concepts as presented herein.

FIG. 1 includes an illustration of one example of an organic electronic device including a new compound described herein.

FIG. 2 includes an illustration of another example of an organic electronic device including a new compound described herein.

Skilled artisans appreciate that objects in the figures are illustrated for simplicity and clarity and have not necessarily been drawn to scale. For example, the dimensions of some of the objects in the figures may be exaggerated relative to other objects to help to improve understanding of embodiments.

### DETAILED DESCRIPTION

Many aspects and embodiments have been described above and are merely exemplary and not limiting. After reading this specification, skilled artisans appreciate that other aspects and embodiments are possible without departing from the scope of the invention. Other features and benefits of any one or more of the embodiments will be apparent from the following detailed description, and from the claims. The detailed description first addresses Definitions and Clarification of Terms followed by the Compounds Comprising Core A, through Core C; Compounds Having Formula I through Formula VI; Compounds Having Formula VII through Formula XI, Devices, and finally Examples.

### 1. Definitions and Clarification of Terms

Before addressing details of embodiments described below, some terms are defined or clarified.

Unless otherwise specifically defined, R, R′, R″ and any other variables are generic designations. The specific definitions for a given formula herein are controlling for that formula.

As used herein, the term “adjacent” as it refers to substituent groups refers to groups that are bonded to carbons that are joined together with a single or multiple bond. Exemplary adjacent R groups are shown below:

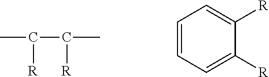

The term “alkoxy” is intended to mean the group RO—, where R is an alkyl group.

The term “alkyl” is intended to mean a group derived from an aliphatic hydrocarbon and includes a linear, a branched, or a cyclic group. A group “derived from” a compound, indicates the radical formed by removal of one or more H or D.

In some embodiments, an alkyl has from 1-20 carbon atoms.

The term “aromatic compound” is intended to mean an organic compound comprising at least one unsaturated cyclic group having 4n+2 delocalized pi electrons.

The term “aryl” is intended to mean a group derived from an aromatic hydrocarbon having one or more points of attachment. The term includes groups which have a single ring and those which have multiple rings which can be joined by a single bond or fused together. Carbocyclic aryl groups have only carbon in the ring structures. Heteroaryl groups have at least one heteroatom in a ring structure.

The term “alkylaryl” is intended to mean an aryl group having one or more alkyl substituents.

The term “aryloxy” is intended to mean the group RO—, where R is an aryl group.

The term “charge transport,” when referring to a layer, material, member, or structure is intended to mean such layer, material, member, or structure facilitates migration of such charge through the thickness of such layer, material, member, or structure with relative efficiency and small loss of charge. Hole transport materials facilitate positive charge; electron transport materials facilitate negative charge. Although light-emitting materials may also have some charge transport properties, the term “charge transport layer, material, member, or structure” is not intended to include a layer, material, member, or structure whose primary function is light emission.

The term “core structure” as it refers to compounds is intended to mean a specific group of atoms bonded together in a specific partial structure.

The term “deuterated” is intended to mean that at least one hydrogen (“H”) has been replaced by deuterium (“D”). The term “deuterated analog” refers to an analog of a compound or group having the same structure but in which one or more available hydrogens have been replaced with deuterium. In a deuterated compound or deuterated analog, the deuterium is present in at least 100 times the natural abundance level. The term “% deuterated” or “% deuteration” is intended to mean the ratio of deuterons to the sum of protons plus deuterons, expressed as a percentage.

The term “dopant” is intended to mean a material, within a layer including a host material, that changes the electronic characteristic(s) or the targeted wavelength(s) of radiation emission, reception, or filtering of the layer compared to the electronic characteristic(s) or the wavelength(s) of radiation emission, reception, or filtering of the layer in the absence of such material.

The abbreviation “FWHM” stands for “full width half maximum” and is intended to mean the width of the emission profile at half the maximum intensity.

The term “germyl” refers to the group R₃Ge—, where R is the same or different at each occurrence and is H, D, C1-20 alkyl, deuterated alkyl, fluoroalkyl, aryl, or deuterated aryl.

The prefix “hetero” indicates that one or more carbon atoms have been replaced with a different atom. In some embodiments, the different atom is N, O, or S.

The term “host material” is intended to mean a material, usually in the form of a layer, to which a dopant may be added. The host material may or may not have electronic characteristic(s) or the ability to emit, receive, or filter radiation.

The terms “luminescent material”, “emissive material” and “emitter” are intended to mean a material that emits light when activated by an applied voltage (such as in a light-emitting diode or light-emitting electrochemical cell). The term “blue luminescent material” is intended to mean a material capable of emitting radiation that has an emission maximum at a wavelength in a range of approximately 445-490 nm.

The term “layer” is used interchangeably with the term “film” and refers to a coating covering a desired area. The term is not limited by size. The area can be as large as an entire device or as small as a specific functional area such as the actual visual display, or as small as a single sub-pixel. Layers and films can be formed by any conventional deposition technique, including vapor deposition, liquid deposition (continuous and discontinuous techniques), and thermal transfer. Continuous deposition techniques, include but are not limited to, spin coating, gravure coating, curtain coating, dip coating, slot-die coating, spray coating, and continuous nozzle coating or printing. Discontinuous deposition techniques include, but are not limited to, ink jet printing, gravure printing, and screen printing.

The term “N-heterocycle” or “N-heteroaryl” refers to a heteroaromatic compound or group having at least one nitrogen in an aromatic ring.

The term “N,O,S-heterocycle” or “N,O,S-heteroaryl” refers to a heteroaromatic compound or group having at least one heteroatom in an aromatic ring, where the heteroatom is N, O, or S. The N,O,S-heterocycle may have more than one type of heteroatom.

The term “organic electronic device” or sometimes just “electronic device” is intended to mean a device including one or more organic semiconductor layers or materials.

The term “photoactive” refers to a material or layer that emits light when activated by an applied voltage (such as in a light emitting diode or chemical cell) or responds to radiant energy and generates a signal with or without an applied bias voltage (such as in a photodetector or a photovoltaic cell). The photoactive material or layer is sometimes referred to as the emissive layer. The photoactive layer is abbreviated herein as “EML”.

The term “siloxane” refers to the group R₃SiO(R₂Si)—, where R is the same or different at each occurrence and is H, D, C1-20 alkyl, deuterated alkyl, fluoroalkyl, aryl, or deuterated aryl. In some embodiments, one or more carbons in an R alkyl group are replaced with Si.

The term “siloxy” refers to the group R₃SiO—, where R is the same or different at each occurrence and is H, D, C1-20 alkyl, deuterated alkyl, fluoroalkyl, aryl, or deuterated aryl.

The term “silyl” refers to the group R₃Si—, where R is the same or different at each occurrence and is H, D, C1-20 alkyl, deuterated alkyl, fluoroalkyl, aryl, or deuterated aryl. In some embodiments, one or more carbons in an R alkyl group are replaced with Si.

All groups may be unsubstituted or substituted. The substituent groups are discussed below. In a structure where a substituent bond passes through one or more rings as shown below,

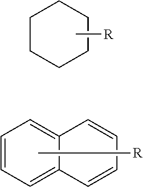

it is meant that the substituent R may be bonded at any available position on the one or more rings.

In any of the formulas or combination of formulas below, any subscript, such as a-h, k, p, q, r, s, a1, b1, and k1, that is present more than one time, may be the same or different at each occurrence.

In this specification, unless explicitly stated otherwise or indicated to the contrary by the context of usage, where an embodiment of the subject matter hereof is stated or described as comprising, including, containing, having, being composed of or being constituted by or of certain features or elements, one or more features or elements in addition to those explicitly stated or described may be present in the embodiment.

An alternative embodiment of the disclosed subject matter hereof, is described as consisting essentially of certain features or elements, in which embodiment features or elements that would materially alter the principle of operation or the distinguishing characteristics of the embodiment are not present therein. A further alternative embodiment of the described subject matter hereof is described as consisting of certain features or elements, in which embodiment, or in insubstantial variations thereof, only the features or elements specifically stated or described are present.

Also, use of “a” or “an” are employed to describe elements and components described herein. This is done merely for convenience and to give a general sense of the scope of the invention. This description should be read to include one or at least one and the singular also includes the plural unless it is obvious that it is meant otherwise.

Group numbers corresponding to columns within the Periodic Table of the elements use the “New Notation” convention as seen in the CRC Handbook of Chemistry and Physics, 81st Edition (2000-2001).

Unless otherwise defined, all technical and scientific terms used herein have the same meaning as commonly understood by one of ordinary skill in the art to which this invention belongs. Although methods and materials similar or equivalent to those described herein can be used in the practice or testing of embodiments of the present invention, suitable methods and materials are described below. In addition, the materials, methods, and examples are illustrative only and not intended to be limiting.

To the extent not described herein, many details regarding specific materials, processing acts, and circuits are conventional and may be found in textbooks and other sources within the organic light-emitting diode display, photodetector, photovoltaic cell, and semiconductive member arts.

2. Compounds Comprising Core A through Core C

In some embodiments, the polycyclic aromatic compounds described herein comprise the core structure Core A

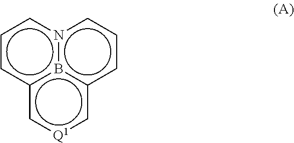

wherein:
Q¹ is selected from the group consisting of a single bond, O, S, NR¹², BR¹², CR¹³R¹⁴, and SiR¹³R¹⁴; and
R¹²-R¹⁴ are the same or different and are selected from the group consisting of alkyl, carbocyclic aryl, heteroaryl, and substituted derivatives thereof.

In some embodiments of Core A, Q¹ is a single bond. By this it is meant that no additional atom is present and the core has the structure below

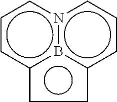

In some embodiments of Core A, Q¹ is O.

In some embodiments of Core A, Q¹ is S.

In some embodiments of Core A, Q¹ is NR¹².

In some embodiments of Core A, Q¹ is BR¹².

In some embodiments of Core A, Q¹ is CR¹³R¹⁴.

In some embodiments of Core A, Q¹ is SiR¹³R¹⁴.

In some embodiments of Core A, R¹² is an alkyl group having 1-12 carbons or a deuterated analog thereof; in some embodiments 1-6 carbons.

In some embodiments of Core A, R¹² is an unsubstituted carbocyclic aryl.

In some embodiments of Core A, R¹² is a carbocyclic aryl or deuterated analog thereof having 6-30 ring carbons; in some embodiments 6-18 ring carbons.

In some embodiments of Core A, R¹² is a substituted carbocyclic aryl, where the substituent is selected from the group consisting of D, alkyl, silyl, germyl, deuterated alkyl, deuterated silyl, and deuterated germyl.

In some embodiments of Core A, R¹² is selected from the group consisting of phenyl, biphenyl, terphenyl, 1-naphthyl, 2-naphthyl, anthracenyl, fluorenyl, phenanthryl, deuterated analogs thereof, and derivatives thereof having one or more substituents selected from the group consisting of D, alkyl, silyl, germyl, carbocyclic aryl, heteroaryl, deuterated alkyl, deuterated silyl, deuterated germyl, deuterated carbocyclic aryl, and deuterated heteroaryl.

In some embodiments of Core A, R¹² is selected from the group consisting of phenyl, biphenyl, terphenyl, 1-naphthyl, 2-naphthyl, anthracenyl, fluorenyl, phenanthryl, deuterated analogs thereof, and derivatives thereof having one or more substituents selected from the group consisting of D, alkyl, silyl, germyl, deuterated alkyl, deuterated silyl, and deuterated germyl.

In some embodiments of Core A, R¹² is selected from the group consisting of phenyl, biphenyl, naphthyl and substituted derivatives thereof.

In some embodiments of Core A, R¹² is an unsubstituted heteroaryl.

In some embodiments of Core A, R¹² is a heteroaryl or deuterated analog thereof having 3-30 ring carbons; in some embodiments 3-18 ring carbons.

In some embodiments of Core A, R¹² is a substituted heteroaryl, where the substituent is selected from the group consisting of D, alkyl, silyl, germyl, deuterated alkyl, deuterated silyl, and deuterated germyl.

In some embodiments of Core A, R¹² is selected from the group consisting of heteroaryl and deuterated heteroaryl, where the heteroaryl has at least one ring atom which is selected from the group consisting of N, O, and S.

In some embodiments of Core A, R¹² is an N-heteroaryl or deuterated N-heteroaryl having at least one ring atom which is N.

In some embodiments of Core A, R¹² is an O-heteroaryl having at least one ring atom that is O. In some embodiments of Core A, R¹² is present and is an S-heteroaryl having at least one ring atom which is S.

In some embodiments of Core A, R¹² is an N,O-heteroaryl having at least one ring atom that is N and at least one ring atom that is O.

All of the above-described embodiments for R¹² in Core A, apply equally to R¹³ and R¹⁴ in Core A.

In some embodiments, the polycyclic aromatic compounds described herein comprise core structure Core B

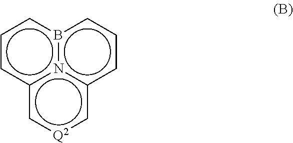

wherein:
Q² is selected from the group consisting of a single bond, O, S, NR¹², BR¹², CR¹³R¹⁴, and SiR¹³R¹⁴; and
R¹²-R¹⁴ are the same or different and are selected from the group consisting of alkyl, carbocyclic aryl, heteroaryl, and substituted derivatives thereof.

All of the above-described embodiments for Q¹ in Core A, apply equally to Q² in Core B.

All of the above-described embodiments for R¹²-R¹⁴ in Core A, apply equally to R¹²-R¹⁴ in Core B.

In some embodiments, the polycylic aromatic compounds described herein comprise core structure Core C

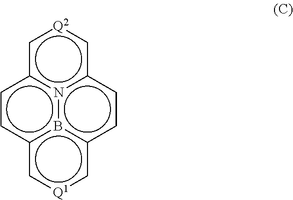

wherein:
Q¹ and Q² are the same or different and are selected from the group consisting of a single bond, O, S, NR¹², BR¹², CR¹³R¹⁴, and SiR¹³R¹⁴; and
R¹²-R¹⁴ are the same or different and are selected from the group consisting of alkyl, carbocyclic aryl, heteroaryl, and substituted derivatives thereof.

In some embodiments of Core C, Q¹=Q².

In some embodiments of Core C, Q¹≠Q².

All of the above-described embodiments for Q¹ in Core A, apply equally to Q¹ and Q² in Core C.

All of the above-described embodiments for R¹²-R¹⁴ in Core A, apply equally to R¹²-R¹⁴ in Core C.

3. Compounds Having Formula I through Formula VI
a. Formula I

In some embodiments, the compounds described herein have Formula I

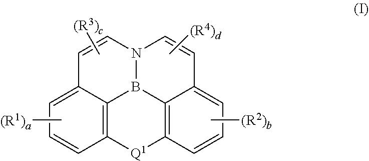

wherein:
Q¹ is selected from the group consisting of a single bond, O, S, NR¹², BR¹², CR¹³R¹⁴, and SiR¹³R¹⁴;
R¹-R⁴ are the same or different at each occurrence and are selected from the group consisting of D, F, CN, alkyl, alkoxy, fluoroalkyl, carbocyclic aryl, aryloxy, heteroaryl, diarylamino, silyl, siloxane, siloxy, germyl, deuterated alkyl, deuterated partially-fluorinated alkyl, deuterated alkoxy, deuterated carbocyclic aryl, deuterated aryloxy, deuterated heteroaryl, deuterated diarylamino, deuterated silyl, deuterated siloxane, deuterated siloxy, and deuterated germyl, where adjacent R groups or R groups on adjacent rings can be joined together to form a 5- or 6-membered cycloaliphatic ring, carbocyclic aromatic ring, heteroaromatic ring, or a substituted derivative thereof;
R¹²-R¹⁴ are the same or different and are selected from the group consisting of alkyl, carbocyclic aryl, heteroaryl, and substituted derivatives thereof;
a and b are the same or different and are an integer from 0-3; and
c and d are the same or different and are an integer from 0-2.

All of the above-described embodiments for Q¹ in Core A, apply equally to Q¹ in Formula I.

In some embodiments of Formula I, a=0.

In some embodiments of Formula I, a=1.

In some embodiments of Formula I, a=2.

In some embodiments of Formula I, a=3.

In some embodiments of Formula I, a>0.

In some embodiments of Formula I, a>0 and at least one R¹=D.

In some embodiments of Formula I, a>0 and at least one R¹ is a C₁₋₂₀ alkyl or deuterated alkyl; in some embodiments, a C₁₋₈ alkyl or deuterated alkyl.

In some embodiments of Formula I, a>0 and at least one R¹ is a C₁₋₂₀ alkoxy or deuterated alkoxy; in some embodiments, a C₁₋₈ alkoxy or deuterated alkoxy.

In some embodiments of Formula I, a>0 and at least one R¹ is a C₁₋₂₀ fluoroalkyl or deuterated fluoroalkyl; in some embodiments, a C₁₋₈ fluoroalkyl or deuterated fluoroalkyl.

In some embodiments of Formula I, a>0 and at least one R¹ is an unsubstituted C₆₋₂₄ carbocyclic aryl; in some embodiments, C₆₋₁₈ carbocyclic aryl.

In some embodiments of Formula I, a>0 and at least one R¹ is a carbocyclic aryl having 6-24 ring carbons and having at least one substituent selected from the group consisting of D, alkyl, silyl, deuterated alkyl, deuterated silyl, and combinations thereof.

In some embodiments of Formula I, a>0 and at least one R¹ is an unsubstituted C₃₋₂₄ heteroaryl; in some embodiments, C₃₋₁₈ heteroaryl.

In some embodiments of Formula I, a>0 and at least one R¹ is a heteroaryl having 6-24 ring carbons and having at least one substituent selected from the group consisting of D, alkyl, silyl, deuterated alkyl, deuterated silyl, and combinations thereof.

In some embodiments of Formula I, a>0 and at least one R¹ is a diarylamino or deuterated diarylamino group having 12-40 ring carbons; in some embodiments, 12-24 ring carbons.

In some embodiments of Formula I, b=0.

In some embodiments of Formula I, b=1.

In some embodiments of Formula I, b=2.

In some embodiments of Formula I, b=3.

In some embodiments of Formula I, b>0.

In some embodiments of Formula I, b>0 and all the above-described embodiments for R¹ apply equally to R².

In some embodiments of Formula I, c=0.

In some embodiments of Formula I, c=1.

In some embodiments of Formula I, c=2.

In some embodiments of Formula I, c>0.

In some embodiments of Formula I, c>0 and all the above-described embodiments for R¹ apply equally to R³.

In some embodiments of Formula I, d=0.

In some embodiments of Formula I, d=1.

In some embodiments of Formula I, d=2.

In some embodiments of Formula I, d>0.

In some embodiments of Formula I, d>0 and all the above-described embodiments for R¹ apply equally to R⁴.

All of the above-described embodiments for R¹², R¹³, and R¹⁴ in Core A, apply equally to R¹², R¹³, and R¹⁴ in Formula I.

In some embodiments of Formula I, a≥2 and two R¹ are joined together to form a fused 5-membered cycloaliphatic ring

In some embodiments of Formula I, a≥2 and two R¹ are joined together to form a fused 6-membered cycloaliphatic ring

In some embodiments, the fused cycloaliphatic ring is further substituted with at least one substituent selected from the group consisting of D, alkyl, silyl, deuterated alkyl, deuterated silyl, and combinations thereof.

In some embodiments of Formula I, a≥2 and two R¹ are joined together to form a fused 5-membered carbocyclic aromatic ring.

In some embodiments of Formula I, a≥2 and two R¹ are joined together to form a fused 6-membered carbocyclic aromatic ring.

In some embodiments, the fused carbocyclic aromatic ring is further substituted with at least one substituent selected from the group consisting of D, alkyl, silyl, deuterated alkyl, deuterated silyl, and combinations thereof.

In some embodiments of Formula I, a≥2 and two R¹ are joined together to form a fused 5-membered heteroaromatic ring.

In some embodiments of Formula I, a≥2 and two R¹ are joined together to form a fused 6-membered heteroaromatic ring.

In some embodiments, the fused heteroaromatic ring is further substituted with at least one substituent selected from the group consisting of D, alkyl, silyl, deuterated alkyl, deuterated silyl, and combinations thereof.

In some embodiments of Formula I, b≥2 and two R² are joined together to form a fused 5-membered cycloaliphatic ring

In some embodiments of Formula I, b≥2 and two R² are joined together to form a fused 6-membered cycloaliphatic ring

In some embodiments, the fused cycloaliphatic ring is further substituted with at least one substituent selected from the group consisting of D, alkyl, silyl, deuterated alkyl, deuterated silyl, and combinations thereof.

In some embodiments of Formula I, b≥2 and two R² are joined together to form a fused 5-membered carbocyclic aromatic ring.

In some embodiments of Formula I, b≥2 and two R² are joined together to form a fused 6-membered carbocyclic aromatic ring.

In some embodiments, the fused carbocyclic aromatic ring is further substituted with at least one substituent selected from the group consisting of D, alkyl, silyl, deuterated alkyl, deuterated silyl, and combinations thereof.

In some embodiments of Formula I, b≥2 and two R² are joined together to form a fused 5-membered heteroaromatic ring.

In some embodiments of Formula I, b≥2 and two R² are joined together to form a fused 6-membered heteroaromatic ring.

In some embodiments, the fused heteroaromatic ring is further substituted with at least one substituent selected from the group consisting of D, alkyl, silyl, deuterated alkyl, deuterated silyl, and combinations thereof.

In some embodiments of Formula I, c≥2 and two R³ are joined together to form a fused 5-membered cycloaliphatic ring

In some embodiments of Formula I, c≥2 and two R³ are joined together to form a fused 6-membered cycloaliphatic ring

In some embodiments, the fused cycloaliphatic ring is further substituted with at least one substituent selected from the group consisting of D, alkyl, silyl, deuterated alkyl, deuterated silyl, and combinations thereof.

In some embodiments of Formula I, c≥2 and two R³ are joined together to form a fused 5-membered carbocyclic aromatic ring.

In some embodiments of Formula I, c≥2 and two R³ are joined together to form a fused 6-membered carbocyclic aromatic ring.

In some embodiments, the fused carbocyclic aromatic ring is further substituted with at least one substituent selected from the group consisting of D, alkyl, silyl, deuterated alkyl, deuterated silyl, and combinations thereof.

In some embodiments of Formula I, c≥2 and two R³ are joined together to form a fused 5-membered heteroaromatic ring.

In some embodiments of Formula I, c≥2 and two R³ are joined together to form a fused 6-membered heteroaromatic ring.

In some embodiments, the fused heteroaromatic ring is further substituted with at least one substituent selected from the group consisting of D, alkyl, silyl, deuterated alkyl, deuterated silyl, and combinations thereof.

In some embodiments of Formula I, d≥2 and two R⁴ are joined together to form a fused 5-membered cycloaliphatic ring

In some embodiments of Formula I, d≥2 and two R⁴ are joined together to form a fused 6-membered cycloaliphatic ring

In some embodiments, the fused cycloaliphatic ring is further substituted with at least one substituent selected from the group consisting of D, alkyl, silyl, deuterated alkyl, deuterated silyl, and combinations thereof.

In some embodiments of Formula I, d≥2 and two R⁴ are joined together to form a fused 5-membered carbocyclic aromatic ring.

In some embodiments of Formula I, d≥2 and two R⁴ are joined together to form a fused 6-membered carbocyclic aromatic ring.

In some embodiments, the fused carbocyclic aromatic ring is further substituted with at least one substituent selected from the group consisting of D, alkyl, silyl, deuterated alkyl, deuterated silyl, and combinations thereof.

In some embodiments of Formula I, d≥2 and two R⁴ are joined together to form a fused 5-membered heteroaromatic ring.

In some embodiments of Formula I, d≥2 and two R⁴ are joined together to form a fused 6-membered heteroaromatic ring.

In some embodiments, the fused heteroaromatic ring is further substituted with at least one substituent selected from the group consisting of D, alkyl, silyl, deuterated alkyl, deuterated silyl, and combinations thereof.

In some embodiments of Formula I, a>0, c>0 and one R¹ and one R³ are joined together to form a fused 5- or 6-membered cycloaliphatic ring.

In some embodiments of Formula I, a>0, c>0 and one R¹ and one R³ are joined together to form a fused 5- or 6-membered carbocyclic aromatic ring.

In some embodiments of Formula I, a>0, c>0 and one R¹ and one R³ are joined together to form a fused 5- or 6-membered heteroaromatic ring.

In some embodiments, the fused cycloaliphatic, carbocyclic aromatic ring, or heterocyclic ring is further substituted with at least one substituent selected from the group consisting of D, alkyl, silyl, deuterated alkyl, deuterated silyl, and combinations thereof.

In some embodiments of Formula I, c>0, d>0 and one R³ and one R⁴ are joined together to form a fused 5- or 6-membered cycloaliphatic ring.

In some embodiments of Formula I, c>0, d>0 and one R³ and one R⁴ are joined together to form a fused 5- or 6-membered carbocyclic aromatic ring.

In some embodiments of Formula I, c>0, d>0 and one R³ and one R⁴ are joined together to form a fused 5- or 6-membered heteroaromatic ring.

In some embodiments, the fused cycloaliphatic, carbocyclic aromatic, or heteroaromatic ring is further substituted with at least one substituent selected from the group consisting of D, alkyl, silyl, deuterated alkyl, deuterated silyl, and combinations thereof.

In some embodiments of Formula I, b>0, d>0 and one R² and one R⁴ are joined together to form a fused 5- or 6-membered cycloaliphatic ring.

In some embodiments of Formula I, b>0, d>0 and one R² and one R⁴ are joined together to form a fused 5- or 6-membered carbocyclic aromatic ring.

In some embodiments of Formula I, b>0, d>0 and one R² and one R⁴ are joined together to form a fused 5- or 6-membered heteroaromatic ring.

In some embodiments, the fused cycloaliphatic, carbocyclic aromatic, or heteroaromatic ring is further substituted with at least one substituent selected from the group consisting of D, alkyl, silyl, deuterated alkyl, deuterated silyl, and combinations thereof.

In some embodiments of Formula I, a>0 and one R¹ is joined together with a substituent on Q¹ to form a 5- or 6-membered cycloaliphatic, carbocyclic aromatic, or heteroaromatic ring, which may optionally be substituted.

In some embodiments of Formula I, b>0 and one R² is joined together with a substituent on Q¹ to form a 5- or 6-membered cycloaliphatic, carbocyclic aromatic, or heteroaromatic ring, which may optionally be substituted.

In some embodiments of Formula I, there are no amino substituent groups present.

In some embodiments of Formula I, there are no carbazolyl substituent groups present.

In some embodiments of Formula I, there are no N-containing organic substituent groups present.

Any of the above embodiments of Formula I can be combined with one or more of the other embodiments, so long as they are not mutually exclusive. For example, the embodiment in which Q¹ is O can be combined with the embodiment where a=1 and R¹ is an unsubstituted carbocyclic aryl, and with the embodiment where c>0, d>0 and one R³ and one R⁴ are joined together to form a fused 5- or 6-membered aromatic ring. The same is true for the other non-mutually-exclusive embodiments discussed above. The skilled person would understand which embodiments were mutually exclusive and would thus readily be able to determine the combinations of embodiments that are contemplated by the present application.

The compounds of Formula I can be made using any technique that will yield a C—C, C—N, C—B, or B—N bond. A variety of such techniques are known, such as Suzuki, Yamamoto, Stille, Negishi, and metal-catalyzed C—N couplings as well as metal catalyzed and oxidative direct arylation, and electrophilic or nucleophilic substitution.

Deuterated compounds can be prepared in a similar manner using deuterated precursor materials or, more generally, by treating the non-deuterated compound with deuterated solvent, such as benzene-d6, in the presence of a Bronsted or Lewis acid H/D exchange catalyst, such as trifluoromethanesulfonic acid, aluminum trichloride or ethyl aluminum dichloride. Deuteration reactions have also been described in published PCT application WO2011/053334.

Exemplary preparations are given in the Examples.

Examples of compounds having Formula I include, but are not limited to, the compounds shown below.

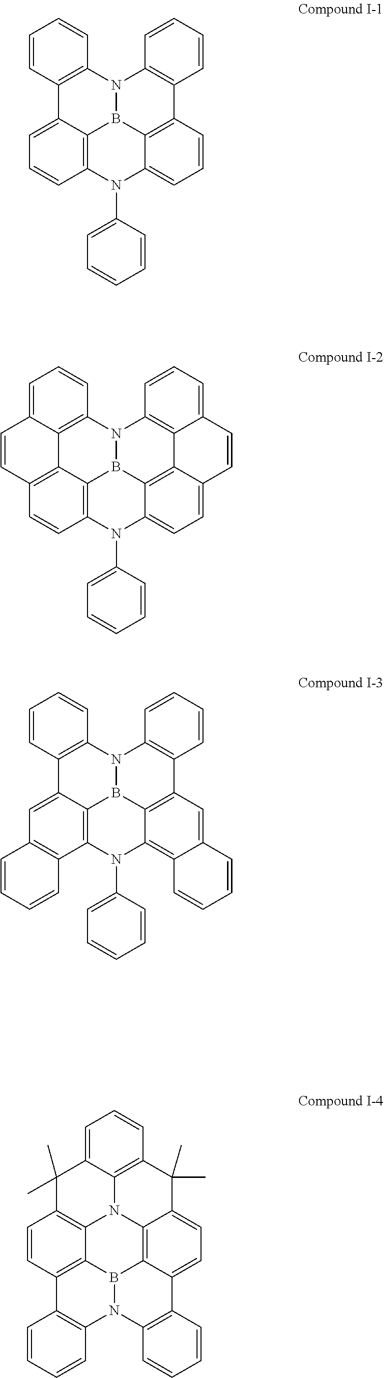

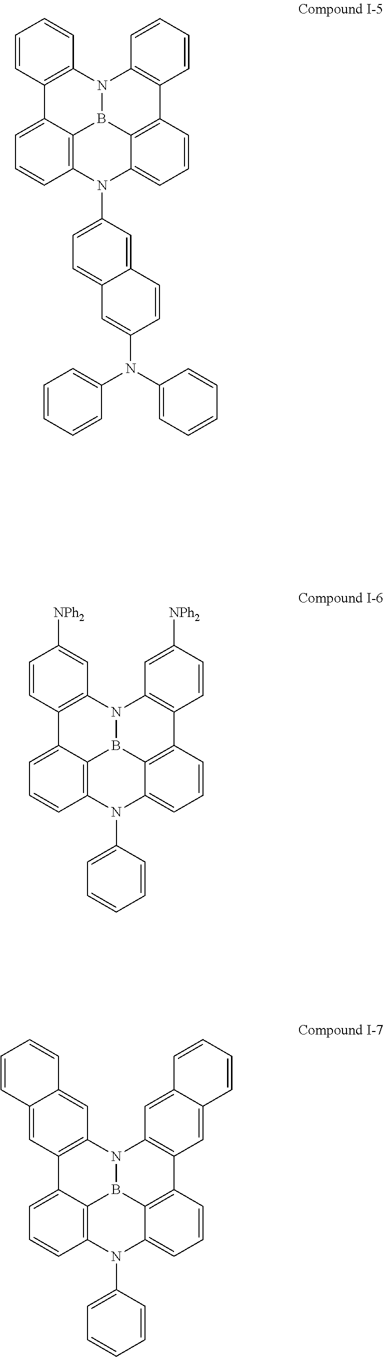

b. Formula II

In some embodiments, the compounds described herein have Formula II

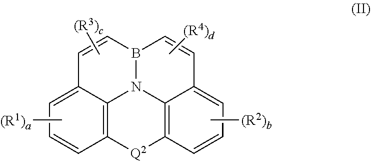

wherein:
Q² is selected from the group consisting of a single bond, O, S, NR¹², BR¹², CR¹³R¹⁴, and SiR¹³R¹⁴;
R¹-R⁴ are the same or different at each occurrence and are selected from the group consisting of D, F, CN, alkyl, alkoxy, fluoroalkyl, carbocyclic aryl, aryloxy, heteroaryl, diarylamino, silyl, siloxane, siloxy, germyl, deuterated alkyl, deuterated partially-fluorinated alkyl, deuterated alkoxy, deuterated carbocyclic aryl, deuterated aryloxy, deuterated heteroaryl, deuterated diarylamino, deuterated silyl, deuterated siloxane, deuterated siloxy, and deuterated germyl, where adjacent R groups or R groups on adjacent rings can be joined together to form a 5- or 6-membered cycloaliphatic ring, carbocyclic aromatic ring, heteroaromatic ring, or a substituted derivative thereof;
R¹²-R¹⁴ are the same or different and are selected from the group consisting of alkyl, carbocyclic aryl, heteroaryl, and substituted derivatives thereof;
a and b are the same or different and are an integer from 0-3; and
c and d are the same or different and are an integer from 0-2.

All of the above-described embodiments for Q¹ in Core A, apply equally to Q² in Formula II.

All of the above-described embodiments for R¹²-R¹⁴, a, b, c, and d in Formula I, apply equally to R¹²-R¹⁴, a, b, c, and d in Formula II.

In some embodiments of Formula II, there are no amino substituent groups present.

In some embodiments of Formula II, there are no carbazolyl substituent groups present.

In some embodiments of Formula II, there are no N-containing organic substituent groups present.

Any of the above embodiments of Formula II can be combined with one or more of the other embodiments, so long as they are not mutually exclusive.

The compounds of Formula II can be made using any technique that will yield a C—C, C—N, C—B, or N—B bond, as described above.

Deuterated compounds can be prepared as described above.

Examples of compounds having Formula II include, but are not limited to, the compounds shown below.

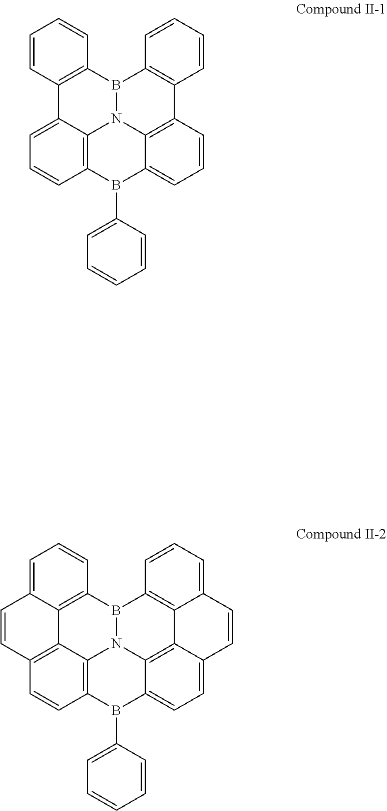 [SMILES: c1ccc(B2c3cccc4c3N3B(c5ccccc5-4)c4ccccc4-c4cccc2c43)cc1 ; c1ccc(B2c3ccc4ccc5cccc6c5c4c3N3B6c4cccc5ccc6ccc2c3c6c45)cc1]

c. Formula III

In some embodiments, the compounds described herein have Formula III

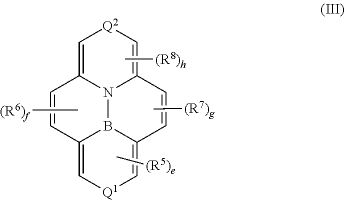

wherein:
Q¹ and Q² are the same or different and are selected from the group consisting of a single bond, O, S, NR¹², BR¹², CR¹³R¹⁴, and SiR¹³R¹⁴;
R⁵-R⁸ are the same or different at each occurrence and are selected from the group consisting of D, F, CN, alkyl, alkoxy, fluoroalkyl, carbocyclic aryl, aryloxy, heteroaryl, diarylamino, silyl, siloxane, siloxy, germyl, deuterated alkyl, deuterated partially-fluorinated alkyl, deuterated alkoxy, deuterated carbocyclic aryl, deuterated aryloxy, deuterated heteroaryl, deuterated diarylamino, deuterated silyl, deuterated siloxane, deuterated siloxy, and deuterated germyl, where adjacent R groups or R groups on adjacent rings can be joined together to form a 5- or 6-membered cycloaliphatic ring, carbocyclic aromatic ring, heteroaromatic ring, or a substituted derivative thereof;
R¹²-R¹⁴ are the same or different and are selected from the group consisting of alkyl, carbocyclic aryl, heteroaryl, and substituted derivatives thereof; and
e-h are the same or different and are an integer from 0-2.

In some embodiments of Formula III, e=0.

In some embodiments of Formula III, e=1.

In some embodiments of Formula III, e=2

In some embodiments of Formula III, e>0.

In some embodiments of Formula III, e>0 and all of the above-described embodiments for R¹ in Formula I apply equally to R⁵ in Formula

In some embodiments of Formula III, f=0.

In some embodiments of Formula III, f=1.

In some embodiments of Formula III, f=2

In some embodiments of Formula III, f>0.

In some embodiments of Formula III, f>0 and all of the above-described embodiments for R¹ in Formula I apply equally to R⁶ in Formula

In some embodiments of Formula III, g=0.

In some embodiments of Formula III, g=1.

In some embodiments of Formula III, g=2

In some embodiments of Formula III, g>0.

In some embodiments of Formula III, g>0 and all of the above-described embodiments for R¹ in Formula I apply equally to R⁷ in Formula III.

In some embodiments of Formula III, h=0.

In some embodiments of Formula III, h=1.

In some embodiments of Formula III, h=2

In some embodiments of Formula III, h>0.

In some embodiments of Formula III, h>0 and all of the above-described embodiments for R¹ in Formula I apply equally to R⁸ in Formula

All of the above-described embodiments for R¹², R¹³, and R¹⁴ in Core A, apply equally to R¹², R¹³, and R¹⁴ in Formula III.

In some embodiments of Formula III, e=2 and two R⁵ are joined together to form a fused 6-membered aromatic ring. In some embodiments, the fused aromatic ring is further substituted with at least one substituent selected from the group consisting of D, alkyl, silyl, deuterated alkyl, deuterated silyl, and combinations thereof.

In some embodiments of Formula III, f=2 and two R⁶ are joined together to form a fused 6-membered aromatic ring. In some embodiments, the fused aromatic ring is further substituted with at least one substituent selected from the group consisting of D, alkyl, silyl, deuterated alkyl, deuterated silyl, and combinations thereof.

In some embodiments of Formula III, g=2 and two R⁷ are joined together to form a fused 6-membered aromatic ring. In some embodiments, the fused aromatic ring is further substituted with at least one substituent selected from the group consisting of D, alkyl, silyl, deuterated alkyl, deuterated silyl, and combinations thereof.

In some embodiments of Formula III, h=2 and two R⁸ are joined together to form a fused 6-membered aromatic ring. In some embodiments, the fused aromatic ring is further substituted with at least one substituent selected from the group consisting of D, alkyl, silyl, deuterated alkyl, deuterated silyl, and combinations thereof.

In some embodiments of Formula III, e>0, f>0 and one R⁵ and one R⁶ are joined together to form a fused 5- or 6-membered aromatic ring. In some embodiments, the fused aromatic ring is further substituted with at least one substituent selected from the group consisting of D, alkyl, silyl, deuterated alkyl, deuterated silyl, and combinations thereof.

In some embodiments of Formula III, f>0, h>0 and one R⁶ and one R⁸ are joined together to form a fused 5- or 6-membered aromatic ring. In some embodiments, the fused aromatic ring is further substituted with at least one substituent selected from the group consisting of D, alkyl, silyl, deuterated alkyl, deuterated silyl, and combinations thereof.

In some embodiments of Formula III, h>0, g>0 and one R⁷ and one R⁸ are joined together to form a fused 5- or 6-membered aromatic ring. In some embodiments, the fused aromatic ring is further substituted with at least one substituent selected from the group consisting of D, alkyl, silyl, deuterated alkyl, deuterated silyl, and combinations thereof.

In some embodiments of Formula III, e>0, g>0 and one R⁵ and one R⁷ are joined together to form a fused 5- or 6-membered aromatic ring. In some embodiments, the fused aromatic ring is further substituted with at least one substituent selected from the group consisting of D, alkyl, silyl, deuterated alkyl, deuterated silyl, and combinations thereof.

In some embodiments of Formula III, there are no amino substituent groups present.

In some embodiments of Formula III, there are no carbazolyl substituent groups present.

In some embodiments of Formula III, there are no N-containing organic substituent groups present.

Any of the above embodiments of Formula III can be combined with one or more of the other embodiments, so long as they are not mutually exclusive.

The compounds of Formula III can be made using any technique that will yield a C—C, C—N, C—B, or N—B bond, as described above.

Deuterated compounds can be prepared as described above. Examples of compounds having Formula III include, but are not limited to, the compounds shown below.

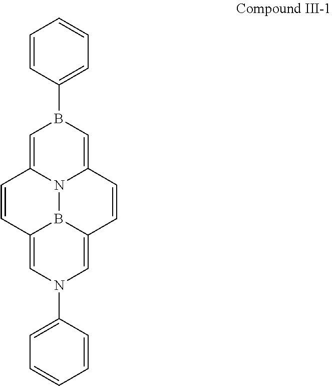 [SMILES: C1=CC2=CB(c3ccccc3)C=C3C=CC4=CN(c5ccccc5)C=C1B4N23]

d. Formula IV

In some embodiments, the compounds described herein have

Formula IV

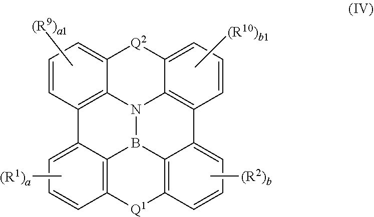

wherein:
Q¹ and Q² are the same or different and are selected from the group consisting of a single bond, O, S, NR¹², BR¹², CR¹³R¹⁴, and SiR¹³R¹⁴;
R¹, R², R⁷, and R⁸ are the same or different at each occurrence and are selected from the group consisting of D, F, CN, alkyl, alkoxy, fluoroalkyl, carbocyclic aryl, aryloxy, heteroaryl, diarylamino, silyl, siloxane, siloxy, germyl, deuterated alkyl, deuterated partially-fluorinated alkyl, deuterated alkoxy, deuterated carbocyclic aryl, deuterated aryloxy, deuterated heteroaryl, deuterated diarylamino, deuterated silyl, deuterated siloxane, deuterated siloxy, and deuterated germyl, where adjacent R groups or R groups on adjacent rings can be joined together to form a 5- or 6-membered cycloaliphatic ring, carbocyclic aromatic ring, heteroaromatic ring, or a substituted derivative thereof;
R¹²-R¹⁴ are the same or different and are selected from the group consisting of alkyl, carbocyclic aryl, heteroaryl, and substituted derivatives thereof; and
a, a1, b, and b1 are the same or different and are an integer from 0-3.

All of the above-described embodiments for Q¹ in Core A, apply equally to Q¹ and Q² in Formula IV.

All of the above-described embodiments for a, b, R¹, and R² in Formula I, apply equally to a, b, R¹, and R² in Formula IV.

All of the above-described embodiments for R¹², R¹³, and R¹⁴ in Core A, apply equally to R¹², R¹³, and R¹⁴ in Formula IV.

In some embodiments of Formula IV, a1=0.

In some embodiments of Formula IV, a1=1.

In some embodiments of Formula IV, a1=2.

In some embodiments of Formula IV, a1=3.

In some embodiments of Formula IV, a1>0.

In some embodiments of Formula IV, a1>0 and all of the above-described embodiments for R¹ in Formula I apply equally to R⁹ in Formula II.

In some embodiments of Formula IV, b1=0.

In some embodiments of Formula IV, b1=1.

In some embodiments of Formula IV, b1=2.

In some embodiments of Formula IV, b1=3.

In some embodiments of Formula IV, b1>0.

In some embodiments of Formula IV, b1>0 and all of the above-described embodiments for R¹ in Formula I apply equally to R¹⁰ in Formula IV.

In some embodiments of Formula IV, a≥2 and two R¹ are joined together to form a fused 6-membered aromatic ring. In some embodiments, the fused aromatic ring is further substituted with at least one substituent selected from the group consisting of D, alkyl, silyl, deuterated alkyl, deuterated silyl, and combinations thereof.

In some embodiments of Formula IV, b≥2 and two R² are joined together to form a fused 6-membered aromatic ring. In some embodiments, the fused aromatic ring is further substituted with at least one substituent selected from the group consisting of D, alkyl, silyl, deuterated alkyl, deuterated silyl, and combinations thereof.

In some embodiments of Formula IV, a1≥2 and two R⁹ are joined together to form a fused 6-membered aromatic ring. In some embodiments, the fused aromatic ring is further substituted with at least one substituent selected from the group consisting of D, alkyl, silyl, deuterated alkyl, deuterated silyl, and combinations thereof.

In some embodiments of Formula IV, b1≥2 and two R¹⁰ are joined together to form a fused 6-membered aromatic ring. In some embodiments, the fused aromatic ring is further substituted with at least one substituent selected from the group consisting of D, alkyl, silyl, deuterated alkyl, deuterated silyl, and combinations thereof.

In some embodiments of Formula IV, a>0, a1>0 and one R¹ and one R⁹ are joined together to form a fused 5- or 6-membered aromatic ring. In some embodiments, the fused aromatic ring is further substituted with at least one substituent selected from the group consisting of D, alkyl, silyl, deuterated alkyl, deuterated silyl, and combinations thereof.

In some embodiments of Formula IV, b>0, b1>0 and one R² and one R¹⁰ are joined together to form a fused 5- or 6-membered aromatic ring. In some embodiments, the fused aromatic ring is further substituted with at least one substituent selected from the group consisting of D, alkyl, silyl, deuterated alkyl, deuterated silyl, and combinations thereof.

In some embodiments of Formula IV, there are no amino substituent groups present.

In some embodiments of Formula IV, there are no carbazolyl substituent groups present. In some embodiments of Formula IV, there are no N-containing organic substituent groups present.

Any of the above embodiments of Formula IV can be combined with one or more of the other embodiments, so long as they are not mutually exclusive.

The compounds of Formula IV can be made using any technique that will yield a C—C, C—N, C—B, or N—B bond, as described above.

Deuterated compounds can be prepared as described above. Examples of compounds having Formula IV include, but are not limited to, the compounds shown below.

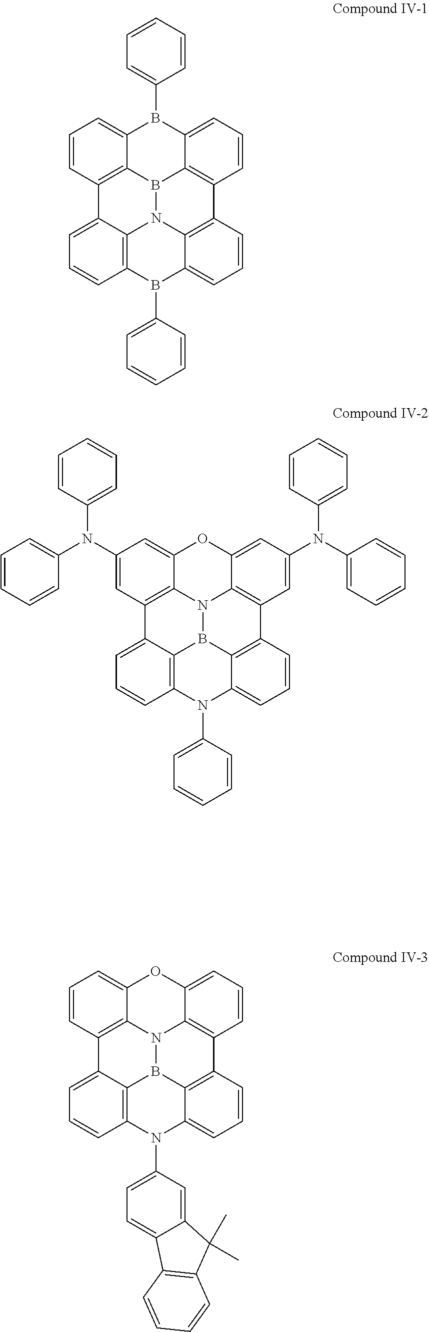 [SMILES: c1ccc(B2c3cccc4c3B3c5c2cccc5-c2cccc5c2N3c2c(cccc2-4)B5c2ccccc2)cc1 ; c1ccc(N(c2ccccc2)c2cc3c4c(c2)-c2cccc5c2B2c6c(cccc6N5c5ccccc5)-c5cc(N(c6ccccc6)c6ccccc6)cc(c5N24)O3)cc1 ; CC1(C)c2ccccc2-c2ccc(N3c4cccc5c4B4c6c(cccc63)-c3cccc6c3N4c3c(cccc3-5)O6)cc21]

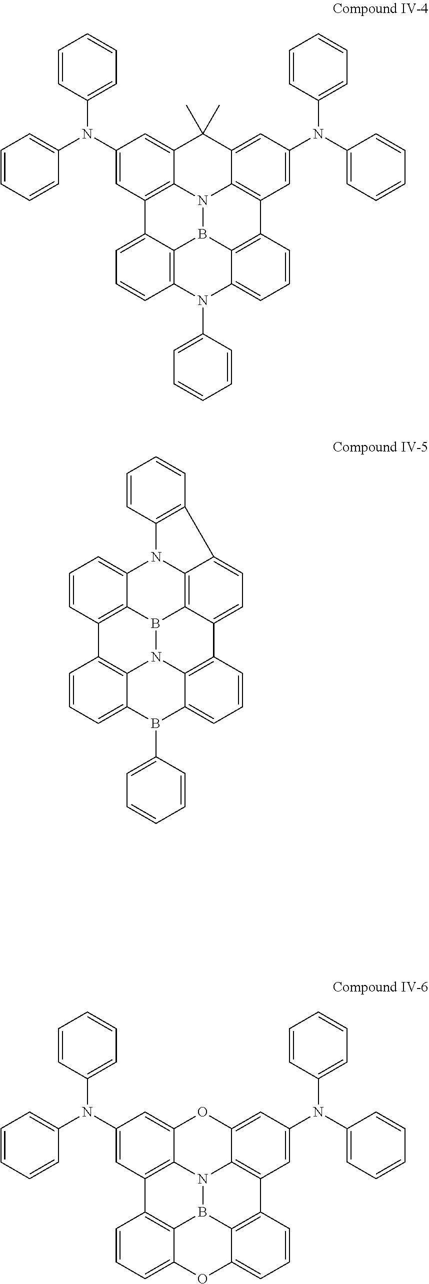 [SMILES: CC1(C)c2cc(N(c3ccccc3)c3ccccc3)cc3c2N2B4c5c-3cccc5N(c3ccccc3)c3cccc(c34)-c3cc(N(c4ccccc4)c4ccccc4)cc1c32 ; c1ccc(B2c3cccc4c3N3B5c6c-4cccc6-n4c6ccccc6c6ccc(c5c64)-c4cccc2c43)cc1 ; c1ccc(N(c2ccccc2)c2cc3c4c(c2)-c2cccc5c2B2c6c(cccc6-c6cc(N(c7ccccc7)c7ccccc7)cc(c6N24)O3)O5)cc1]

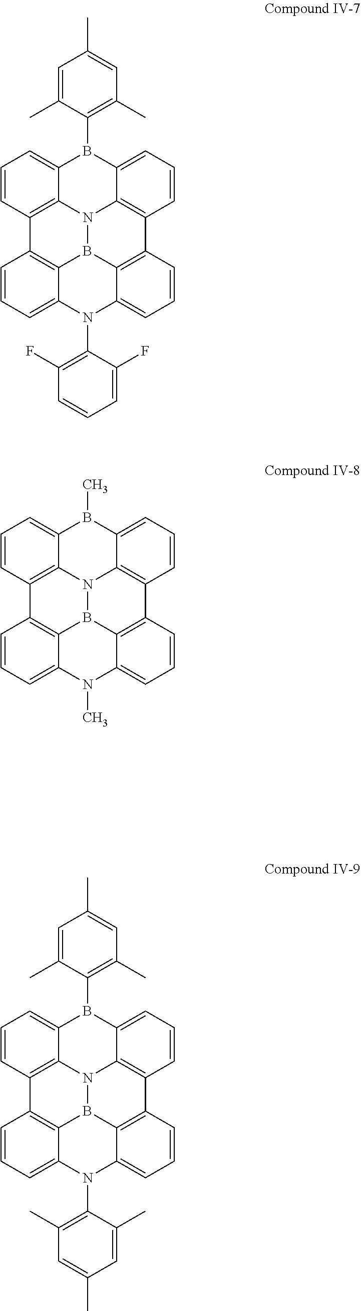 [SMILES: Cc1cc(C)c(B2c3cccc4c3N3B5c6c-4cccc6N(c4c(F)cccc4F)c4cccc(c45)-c4cccc2c43)c(C)c1 ; CB1c2cccc3c2N2B4c5c-3cccc5N(C)c3cccc(c34)-c3cccc1c32 ; Cc1cc(C)c(B2c3cccc4c3N3B5c6c-4cccc6N(c4c(C)cc(C)cc4C)c4cccc(c45)-c4cccc2c43)c(C)c1]

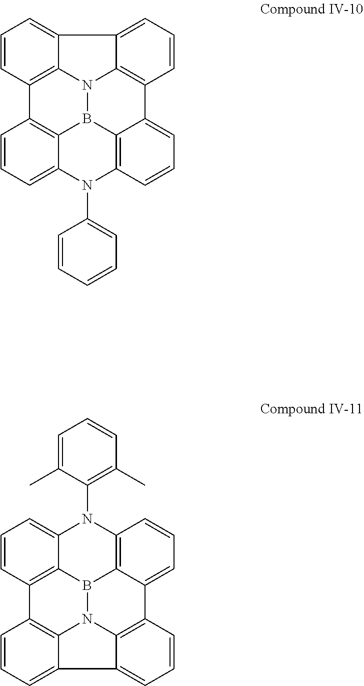 [SMILES: c1ccc(N2c3cccc4c3B3c5c(cccc52)-c2cccc5c6cccc-4c6n3c25)cc1 ; Cc1cccc(C)c1N1c2cccc3c2B2c4c(cccc41)-c1cccc4c5cccc-3c5n2c14]

e. Formula V

In some embodiments, the compounds described herein have Formula V

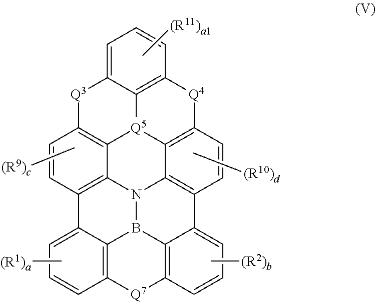

wherein:
Q³-Q⁴ are the same or different and are selected from the group consisting of a single bond, O, S, NR¹², BR¹², CR¹³R¹⁴, and SiR¹³R¹⁴;
Q⁵ is selected from the group consisting of N, B, P(O), CR¹³, and SiR₁₃;
Q⁷ is selected from the group consisting no bond, a single bond, O, S, NR¹², BR¹², CR¹³R¹⁴, and SiR¹³R¹⁴;
R¹, R², R⁹, and R¹⁰ are the same or different at each occurrence and are selected from the group consisting of D, F, CN, alkyl, alkoxy, fluoroalkyl, carbocyclic aryl, aryloxy, heteroaryl, diarylamino, silyl, siloxane, siloxy, germyl, deuterated alkyl, deuterated partially-fluorinated alkyl, deuterated alkoxy, deuterated carbocyclic aryl, deuterated aryloxy, deuterated heteroaryl, deuterated diarylamino, deuterated silyl, deuterated siloxane, deuterated siloxy, and deuterated germyl, where adjacent R groups or R groups on adjacent rings can be joined together to form a 5- or 6-membered cycloaliphatic ring, carbocyclic aromatic ring, heteroaromatic ring, or a substituted derivative thereof;
R¹²-R¹⁴ are the same or different and are selected from the group consisting of alkyl, carbocyclic aryl, heteroaryl, and substituted derivatives thereof;
a, a1, and b are the same or different and are an integer from 0-3; and
c and d are the same or different and are an integer from 0-2.

All of the above-described embodiments for Q¹ in Core A, apply equally to Q³ and Q⁴ in Formula V.

All of the above-described embodiments for R¹, R², a, b, c, and d in Formula I, apply equally to R¹, R², a, b, c, and d in Formula V.

All of the above-described embodiments for R¹², R¹³, and R¹⁴ in Core A, apply equally to R¹², R¹³, and R¹⁴ in Formula V.

All of the above-described embodiments for al in Formula IV, apply equally to al in Formula V.

In some embodiments of Formula V, Q⁵ is N.

In some embodiments of Formula V, Q⁵ is B.

In some embodiments of Formula V, Q⁵ is P(O).

In some embodiments of Formula V, Q⁵ is CR¹³.

In some embodiments of Formula V, Q⁵ is SiR¹³.

In some embodiments of Formula V, Q⁷ is no bond. By this it is mean that there is no connecting bond and the formula is as shown below:

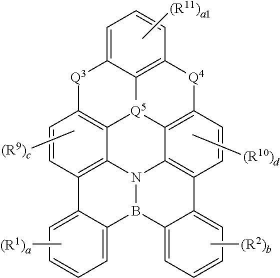

In some embodiments of Formula V, Q⁷ is a single bond.

In some embodiments of Formula V, Q⁷ is O.

In some embodiments of Formula V, Q⁷ is S.

In some embodiments of Formula V, Q⁷ is NR¹².

In some embodiments of Formula V, Q⁷ is BR¹².

In some embodiments of Formula V, Q⁷ is CR¹³R¹⁴.

In some embodiments of Formula V, Q⁷ is SiR¹³R¹⁴.

In some embodiments of Formula V, c>0 and all of the above-described embodiments for R¹ in Formula I apply equally to R⁹ in Formula V.

In some embodiments of Formula V, d>0 and all of the above-described embodiments for R¹ in Formula I apply equally to R¹⁰ in Formula V.

In some embodiments of Formula V, a1>0 and all of the above-described embodiments for R¹ in Formula I apply equally to R¹¹ in Formula V. Any of the above embodiments of Formula V can be combined with one or more of the other embodiments, so long as they are not mutually exclusive.

The compounds of Formula V can be made using any technique that will yield a C—C, C—N, C—B, or N—B bond, as described above. Deuterated compounds can be prepared as described above.

Examples of compounds having Formula V include, but are not limited to, the compounds shown below.

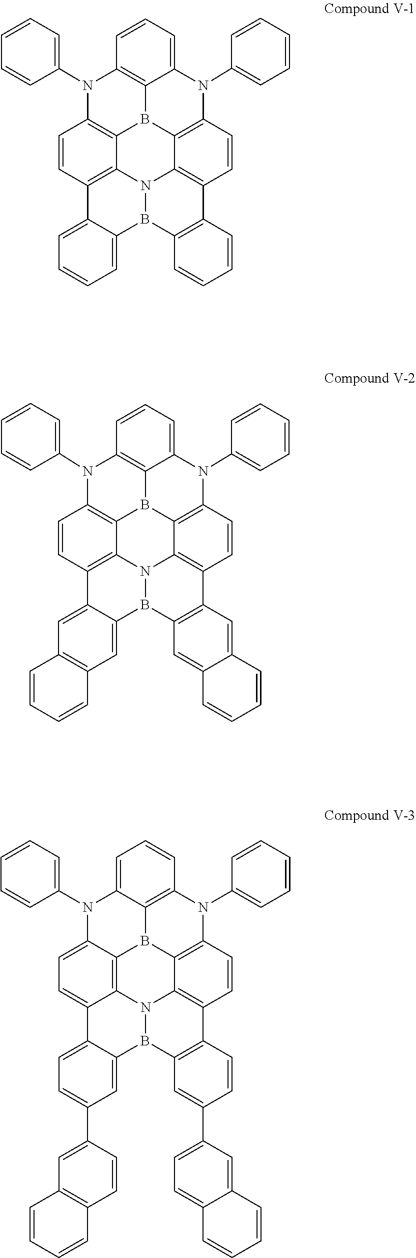 [SMILES: c1ccc(N2c3cccc4c3B3c5c2ccc2c5N5B(c6ccccc6-2)c2ccccc2-c2ccc(c3c25)N4c2ccccc2)cc1 ; c1ccc(N2c3cccc4c3B3c5c2ccc2c5N5B(c6cc7ccccc7cc6-2)c2cc6ccccc6cc2-c2ccc(c3c25)N4c2ccccc2)cc1 ; c1ccc(N2c3cccc4c3B3c5c2ccc2c5N5B(c6cc(-c7ccc8ccccc8c7)ccc6-2)c2cc(-c6ccc7ccccc7c6)ccc2-c2ccc(c3c25)N4c2ccccc2)cc1]

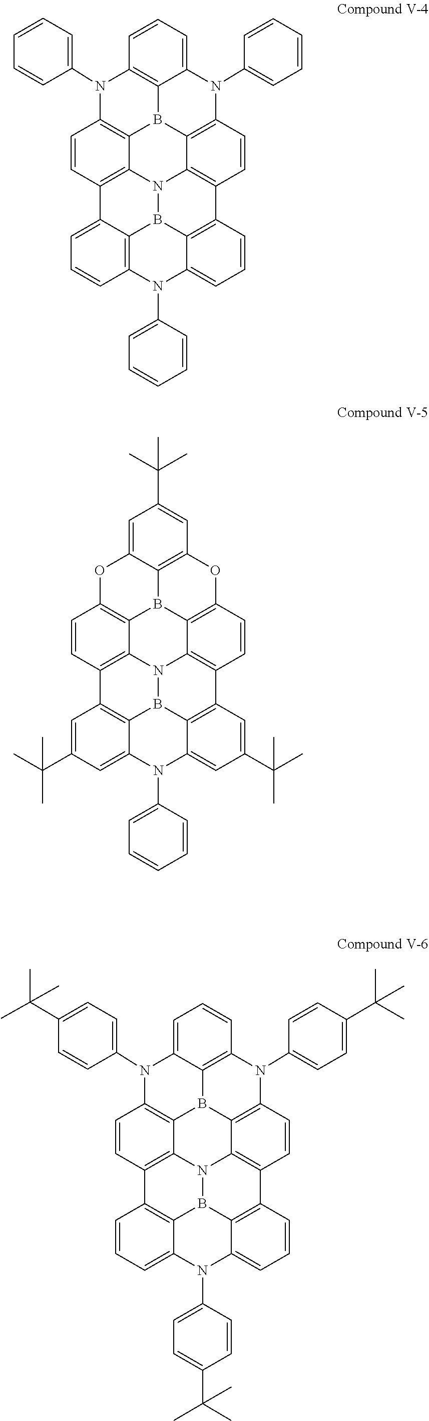

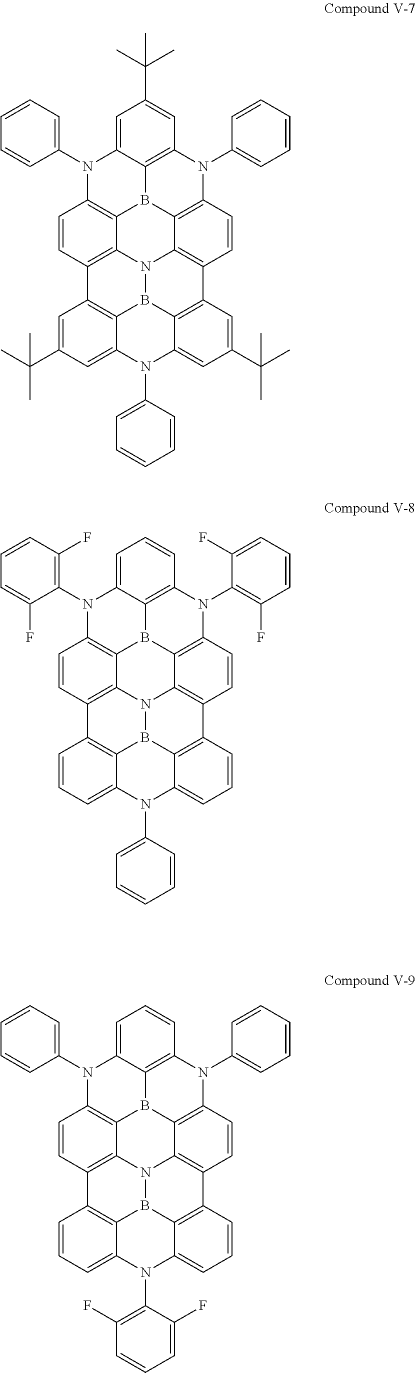 [SMILES: CC(C)(C)c1cc2c3c(c1)N(c1ccccc1)c1cc(C(C)(C)C)cc4c1B3N1c3c-2ccc2c3B3c5c(cc(C(C)(C)C)cc5N(c5ccccc5)c5ccc-4c1c53)N2c1ccccc1 ; Fc1cccc(F)c1N1c2cccc3c2B2c4c1ccc1c4N4B5c6c-1cccc6N(c1ccccc1)c1cccc(c15)-c1ccc(c2c14)N3c1c(F)cccc1F ; Fc1cccc(F)c1N1c2cccc3c2B2c4c(cccc41)-c1ccc4c5c1N2c1c-3ccc2c1B5c1c(cccc1N4c1ccccc1)N2c1ccccc1]

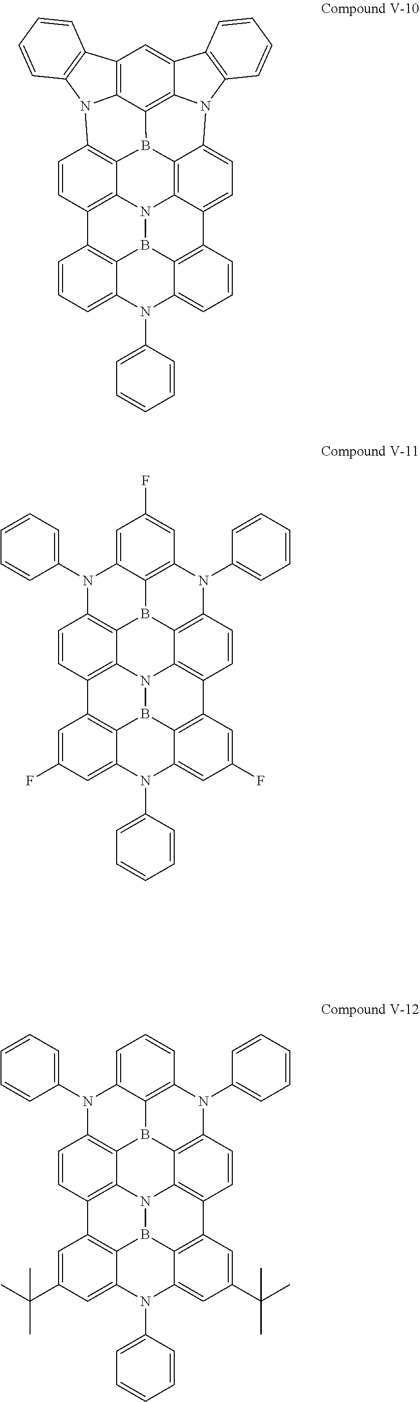 [SMILES: c1ccc(N2c3cccc4c3B3c5c(cccc52)-c2ccc5c6c2N3c2c-4ccc3c2B6c2c4c(cc6c7ccccc7n-5c26)c2ccccc2n4-3)cc1 ; Fc1cc2c3c(c1)N(c1ccccc1)c1cc(F)cc4c1B3N1c3c-2ccc2c3B3c5c(cc(F)cc5N(c5ccccc5)c5ccc-4c1c53)N2c1ccccc1 ; CC(C)(C)c1cc2c3c(c1)N(c1ccccc1)c1cc(C(C)(C)C)cc4c1B3N1c3c-2ccc2c3B3c5c(cccc5N(c5ccccc5)c5ccc-4c1c53)N2c1ccccc1]

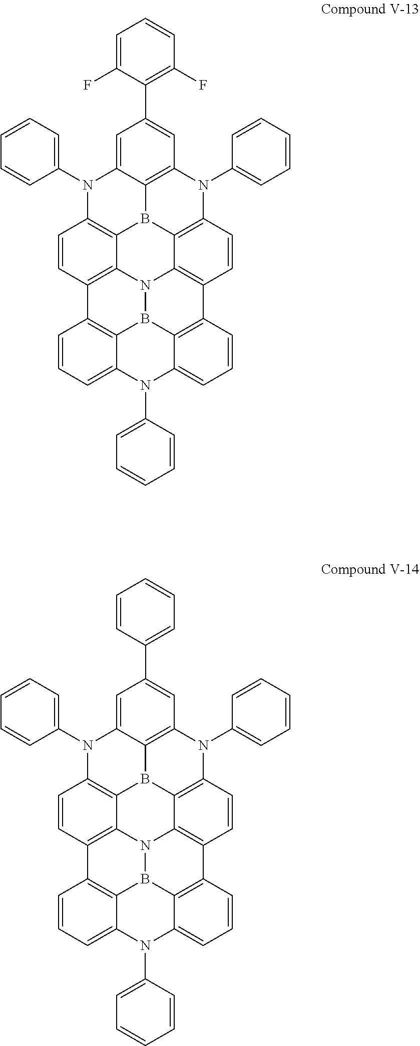 [SMILES: Fc1cccc(F)c1-c1cc2c3c(c1)N(c1ccccc1)c1ccc4c5c1B3c1c(ccc3c1N5B1c5c-3cccc5N(c3ccccc3)c3cccc-4c31)N2c1ccccc1 ; c1ccc(-c2cc3c4c(c2)N(c2ccccc2)c2ccc5c6c2B4c2c(ccc4c2N6B2c6c-4cccc6N(c4ccccc4)c4cccc-5c42)N3c2ccccc2)cc1]

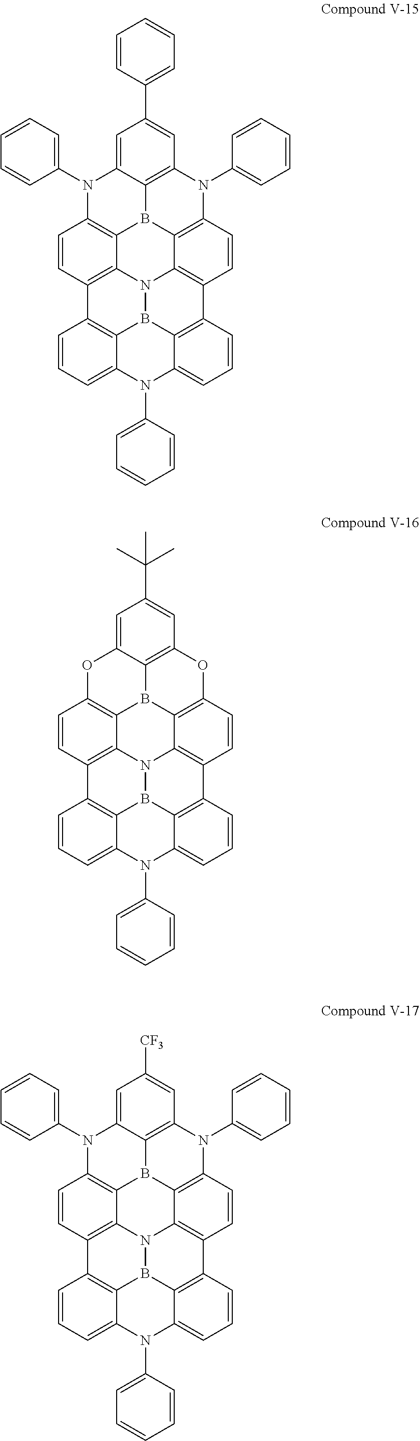

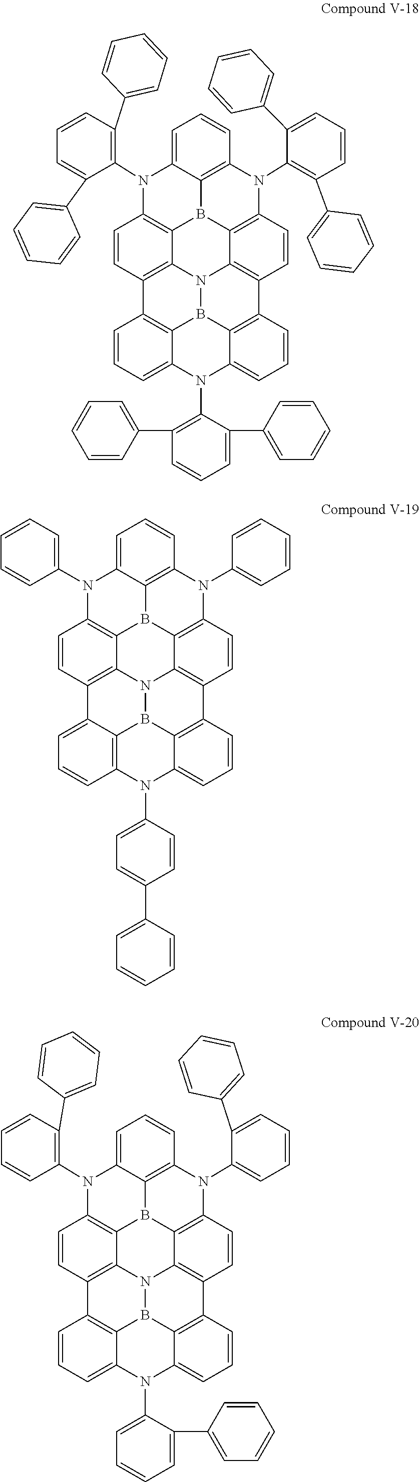 [SMILES: c1ccc(-c2cccc(-c3ccccc3)c2N2c3cccc4c3B3c5c(cccc52)-c2ccc5c6c2N3c2c-4ccc3c2B6c2c(cccc2N5c2c(-c4ccccc4)cccc2-c2ccccc2)N3c2c(-c3ccccc3)cccc2-c2ccccc2)cc1 ; c1ccc(-c2ccc(N3c4cccc5c4B4c6c(cccc63)-c3ccc6c7c3N4c3c-5ccc4c3B7c3c(cccc3N6c3ccccc3)N4c3ccccc3)cc2)cc1 ; c1ccc(-c2ccccc2N2c3cccc4c3B3c5c(cccc52)-c2ccc5c6c2N3c2c-4ccc3c2B6c2c(cccc2N5c2ccccc2-c2ccccc2)N3c2ccccc2-c2ccccc2)cc1]

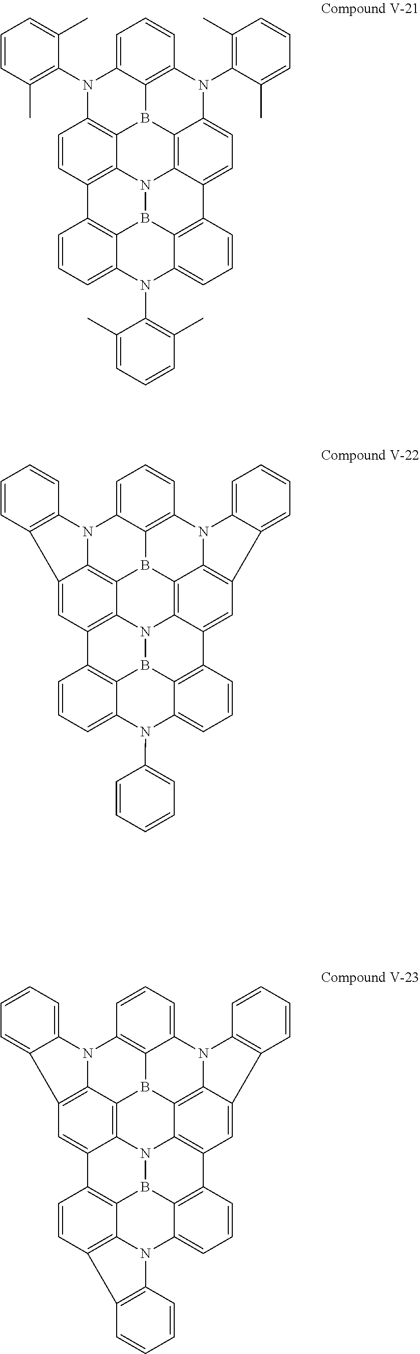 [SMILES: Cc1cccc(C)c1N1c2cccc3c2B2c4c(cccc41)-c1ccc4c5c1N2c1c-3ccc2c1B5c1c(cccc1N4c1c(C)cccc1C)N2c1c(C)cccc1C ; c1ccc(N2c3cccc4c3B3c5c(cccc52)-c2cc5c6ccccc6n6c5c5c2N3c2c-4cc3c4ccccc4n4c3c2B5c2c-4cccc2-6)cc1 ; c1cc2c3c(c1)-n1c4ccccc4c4ccc5c(c41)B3N1c3c-2cc2c4ccccc4n4c2c3B2c3c-4cccc3-n3c4ccccc4c4cc-5c1c2c43]

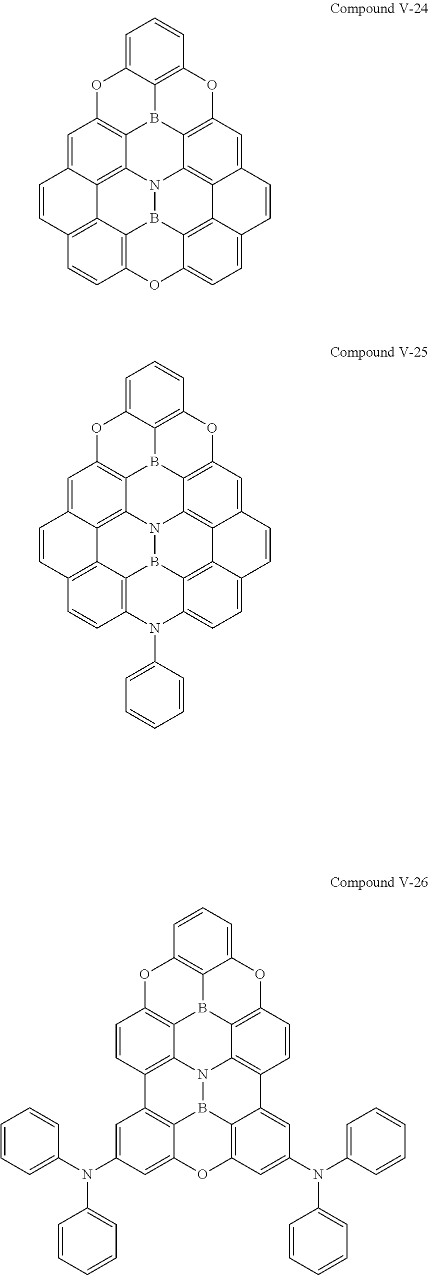 [SMILES: c1cc2c3c(c1)Oc1cc4ccc5ccc6c7c5c4c4c1B3c1c(cc3ccc5ccc(c8c5c3c1N4B87)O6)O2 ; c1ccc(N2c3ccc4ccc5cc6c7c8c5c4c3B3c4c2ccc2ccc5cc9c(c(c5c42)N38)B7c2c(cccc2O9)O6)cc1 ; c1ccc(N(c2ccccc2)c2cc3c4c(c2)-c2ccc5c6c2N2B4c4c(cc(N(c7ccccc7)c7ccccc7)cc4-c4ccc7c(c42)B6c2c(cccc2O7)O5)O3)cc1]

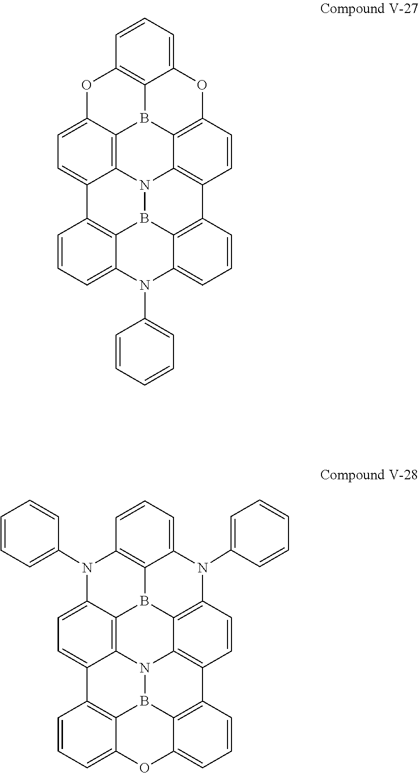 [SMILES: c1ccc(N2c3cccc4c3B3c5c(cccc52)-c2ccc5c6c2N3c2c-4ccc3c2B6c2c(cccc2O5)O3)cc1 ; c1ccc(N2c3cccc4c3B3c5c2ccc2c5N5B6c7c(cccc7-2)Oc2cccc(c26)-c2ccc(c3c25)N4c2ccccc2)cc1]

f. Formula VI

In some embodiments, the compounds described herein have Formula VI

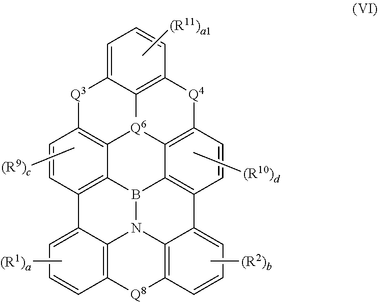

wherein:
Q³ and Q⁴ are the same or different and are selected from the group consisting of a single bond, O, S, NR¹², BR₁₂, CR¹³R¹⁴, and SiR¹³R¹⁴;
Q⁶ is selected from the group consisting of N, B, P(O), CR¹³, and S_{iR}¹³;

Q⁸ is selected from the group consisting no bond, a single bond, O, S, NR¹², BR¹², CR¹³R¹⁴, and SiR¹³R¹⁴;
R¹, R², R⁹, and R¹⁰ are the same or different at each occurrence and are selected from the group consisting of D, F, CN, alkyl, alkoxy, fluoroalkyl, carbocyclic aryl, aryloxy, heteroaryl, diarylamino, silyl, siloxane, siloxy, germyl, deuterated alkyl, deuterated partially-fluorinated alkyl, deuterated alkoxy, deuterated carbocyclic aryl, deuterated aryloxy, deuterated heteroaryl, deuterated diarylamino, deuterated silyl, deuterated siloxane, deuterated siloxy, and deuterated germyl, where adjacent R groups or R groups on adjacent rings can be joined together to form a 5- or 6-membered cycloaliphatic ring, carbocyclic aromatic ring, heteroaromatic ring, or a substituted derivative thereof;
R¹²-R¹⁴ are the same or different and are selected from the group consisting of alkyl, carbocyclic aryl, heteroaryl, and substituted derivatives thereof;
a, a1, and b are the same or different and are an integer from 0-3; and
c and d are the same or different and are an integer from 0-2.

All of the above-described embodiments for Q⁵ in Formula V, apply equally to Q⁶ in Formula VI.

All of the above-described embodiments for Q⁷ in Formula V, apply equally to Q⁸ in Formula VI.

All of the above-described embodiments for R¹, R², R⁹, and R¹⁰, a, a1, b, c, and d in Formula V apply equally to R¹, R², R⁹, and R¹⁰, a, a1, b, c, and d in Formula VI.

All of the above-described embodiments for R¹², R¹³, and R¹⁴ in Core A, apply equally to R¹², R¹³, and R¹⁴ in Formula VI.

Any of the above embodiments of Formula VI can be combined with one or more of the other embodiments, so long as they are not mutually exclusive.

The compounds of Formula VI can be made using any technique that will yield a C—C, C—N, C—B, or N—B bond, as described above.

Deuterated compounds can be prepared as described above.

Examples of compounds having Formula VI include, but are not limited to, the compounds shown below.

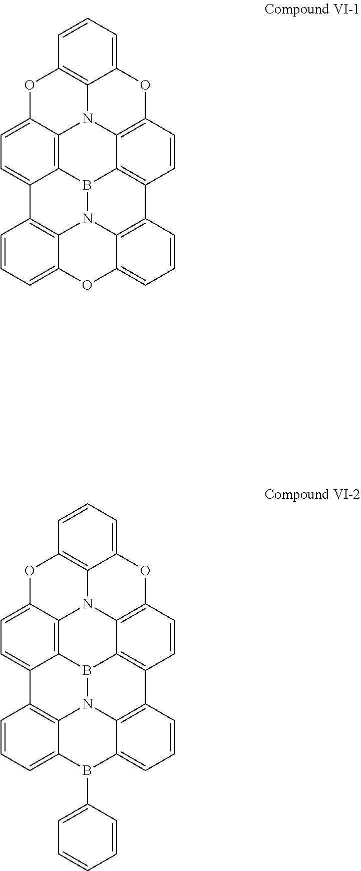 [SMILES: c1cc2c3c(c1)Oc1ccc4c5c1N3c1c(ccc3c1B5N1c5c(cccc5-3)Oc3cccc-4c31)O2 ; c1ccc(B2c3cccc4c3N3B5c6c-4ccc4c6N6c7c(cccc7Oc7ccc(c5c76)-c5cccc2c53)O4)cc1]

4. Compounds Having Formula VII through Formula XI

In some embodiments, the polycyclic aromatic compound comprises two boron-nitrogen bonds.

In some embodiments, the polycyclic aromatic compound described herein has Formula VII

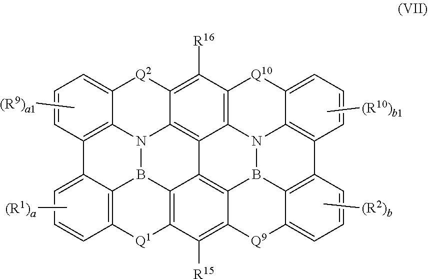

wherein:
Q¹, Q², Q⁹, and Q¹⁰ are the same or different and are selected from the group consisting of a single bond, O, S, NR¹², BR¹², CR¹³R¹⁴, and SiR¹³R¹⁴; and
R¹, R², R⁹, and R¹⁰ are the same or different at each occurrence and are selected from the group consisting of D, F, CN, alkyl, alkoxy, fluoroalkyl, carbocyclic aryl, aryloxy, heteroaryl, diarylamino, silyl, siloxane, siloxy, germyl, deuterated alkyl, deuterated partially-fluorinated alkyl, deuterated alkoxy, deuterated carbocyclic aryl, deuterated aryloxy, deuterated heteroaryl, deuterated diarylamino, deuterated silyl, deuterated siloxane, deuterated siloxy, and deuterated germyl, where adjacent R groups or R groups on adjacent rings can be joined together to form a 5- or 6-membered cycloaliphatic ring, carbocyclic aromatic ring, heteroaromatic ring, or a substituted derivative thereof;
R¹²-R¹⁴ are the same or different and are selected from the group consisting of alkyl, carbocyclic aryl, heteroaryl, and substituted derivatives thereof;
R¹⁵ and R¹⁶ are the same or different at each occurrence and are selected from the group consisting of H, D, F, CN, alkyl, alkoxy, fluoroalkyl, carbocyclic aryl, aryloxy, heteroaryl, diarylamino, silyl, siloxane, siloxy, germyl, deuterated alkyl, deuterated partially-fluorinated alkyl, deuterated alkoxy, deuterated carbocyclic aryl, deuterated aryloxy, deuterated heteroaryl, deuterated diarylamino, deuterated silyl, deuterated siloxane, deuterated siloxy, and deuterated germyl, where adjacent R groups or R groups on adjacent rings can be joined together to form a 5- or 6-membered cycloaliphatic ring, carbocyclic aromatic ring, heteroaromatic ring, or a substituted derivative thereof; and
a, a1, b, and b1 are the same or different and are an integer from 0-3.

All of the above-described embodiments for Q¹ in Core A, apply equally to Q¹, Q², Q⁹, and Q¹⁰ in Formula VII.

All of the above-described embodiments for R¹ in Formula I, apply equally to R¹, R², R⁹, and R¹⁰ in Formula VII.

All of the above-described embodiments for R¹²-R¹⁴ in Core A, apply equally to R¹²-R¹⁴ in Formula VII.

All of the above-described embodiments for a, a1, b, and b1 in Formula IV, apply equally to a, a1, b, and b1 in Formula VII.

In some embodiments of Formula VII, R¹⁵=H.

In some embodiments of Formula VII, R¹⁵=D.

In some embodiments of Formula VII, R¹⁵ is a C₁₋₂₀ alkyl or deuterated alkyl; in some embodiments, a C₁₋₈ alkyl or deuterated alkyl.

In some embodiments of Formula VII, R¹⁵ is a C₁₋₂₀ alkoxy or deuterated alkoxy; in some embodiments, a C₁₋₈ alkoxy or deuterated alkoxy.

In some embodiments of Formula VII, R¹⁵ is a C₁₋₂₀ fluoroalkyl or deuterated fluoroalkyl; in some embodiments, a C₁₋₈ fluoroalkyl or deuterated fluoroalkyl.

In some embodiments of Formula VII, R¹⁵ is an unsubstituted C₆₋₂₄ carbocyclic aryl; in some embodiments, C₆₋₁₈ carbocyclic aryl.

In some embodiments of Formula VII, R¹⁵ is a carbocyclic aryl having 6-24 ring carbons and having at least one substituent selected from the group consisting of D, alkyl, silyl, deuterated alkyl, deuterated silyl, and combinations thereof.

In some embodiments of Formula VII, R¹⁵ is an unsubstituted C₃₋₂₄ heteroaryl; in some embodiments, C₃₋₁₈ heteroaryl.

In some embodiments of Formula VII, R¹⁵ is a heteroaryl having 6-24 ring carbons and having at least one substituent selected from the group consisting of D, alkyl, silyl, deuterated alkyl, deuterated silyl, and combinations thereof.

In some embodiments of Formula VII, R¹⁵ is a diarylamino or deuterated diarylamino group having 12-40 ring carbons; in some embodiments, 12-24 ring carbons.

All of the above-described embodiments for R¹⁵ in Formula VII, apply equally to R¹⁵ in Formula VII.

Any of the above embodiments of Formula VII can be combined with one or more of the other embodiments, so long as they are not mutually exclusive.

The compounds of Formula VII can be made using any technique that will yield a C—C, C—N, C—B, or N—B bond, as described above.

Deuterated compounds can be prepared as described above.

In some embodiments, the polycyclic aromatic compound described herein has Formula VIII

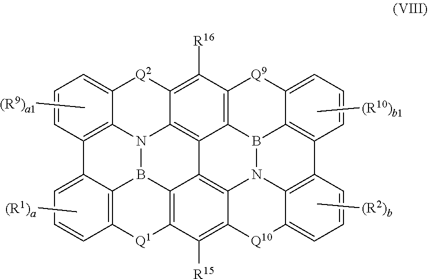

wherein:
Q¹, Q², Q⁹, and Q¹⁰ are the same or different and are selected from the group consisting of a single bond, O, S, NR¹², BR¹², CR¹³R¹⁴, and SiR¹³R¹⁴; and
R¹, R², R⁶, R⁷, R⁹, and R¹⁰ are the same or different at each occurrence and are selected from the group consisting of D, F, CN, alkyl, alkoxy, fluoroalkyl, carbocyclic aryl, aryloxy, heteroaryl, diarylamino, silyl, siloxane, siloxy, germyl, deuterated alkyl, deuterated partially-fluorinated alkyl, deuterated alkoxy, deuterated carbocyclic aryl, deuterated aryloxy, deuterated heteroaryl, deuterated diarylamino, deuterated silyl, deuterated siloxane, deuterated siloxy, and deuterated germyl, where adjacent R groups or R groups on adjacent rings can be joined together to form a 5- or 6-membered cycloaliphatic ring, carbocyclic aromatic ring, heteroaromatic ring, or a substituted derivative thereof;
R¹²-R¹⁴ are the same or different and are selected from the group consisting of alkyl, carbocyclic aryl, heteroaryl, and substituted derivatives thereof;
R¹⁵ and R¹⁶ are the same or different at each occurrence and are selected from the group consisting of H, D, F, CN, alkyl, alkoxy, fluoroalkyl, carbocyclic aryl, aryloxy, heteroaryl, diarylamino, silyl, siloxane, siloxy, germyl, deuterated alkyl, deuterated partially-fluorinated alkyl, deuterated alkoxy, deuterated carbocyclic aryl, deuterated aryloxy, deuterated heteroaryl, deuterated diarylamino, deuterated silyl, deuterated siloxane, deuterated siloxy, and deuterated germyl, where adjacent R groups or R groups on adjacent rings can be joined together to form a 5- or 6-membered cycloaliphatic ring, carbocyclic aromatic ring, heteroaromatic ring, or a substituted derivative thereof;
a, a1, b, and b1 are the same or different and are an integer from 0-3; and
c and d are the same or different and are an integer from 0-2.

All of the above-described embodiments for Q¹ in Core A, apply equally to Q¹, Q², Q⁹, and Q¹⁰ in Formula VIII.

All of the above-described embodiments for R¹ in Formula I, apply equally to R¹, R², R⁹, and R¹⁰ in Formula VIII.

All of the above-described embodiments for R¹²-R¹⁴ in Core A, apply equally to R¹²-R¹⁴ in Formula VIII.

All of the above-described embodiments for a, a1, b, and b1 in Formula IV, apply equally to a, a1, b, and b1 in Formula VIII.

All of the above-described embodiments for R¹⁵ in Formula VII, apply equally to R¹⁵ and R¹⁶ in Formula VIII.

Any of the above embodiments of Formula VIII can be combined with one or more of the other embodiments, so long as they are not mutually exclusive.

The compounds of Formula VIII can be made using any technique that will yield a C—C, C—N, C—B, or N—B bond, as described above.

Deuterated compounds can be prepared as described above.

In some embodiments, the polycyclic aromatic compound described herein has Formula IX

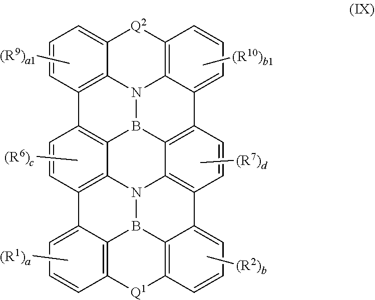

wherein:
Q¹ and Q² are the same or different and are selected from the group consisting of a single bond, O, S, NR¹², BR₁₂, CR¹³R¹⁴, and SiR¹³R¹⁴; and
R¹, R², R⁶, R⁷, R⁹, and R¹⁰ are the same or different at each occurrence and are selected from the group consisting of D, F, CN, alkyl, alkoxy, fluoroalkyl, carbocyclic aryl, aryloxy, heteroaryl, diarylamino, silyl, siloxane, siloxy, germyl, deuterated alkyl, deuterated partially-fluorinated alkyl, deuterated alkoxy, deuterated carbocyclic aryl, deuterated aryloxy, deuterated heteroaryl, deuterated diarylamino, deuterated silyl, deuterated siloxane, deuterated siloxy, and deuterated germyl, where adjacent R groups or R groups on adjacent rings can be joined together to form a 5- or 6-membered cycloaliphatic ring, carbocyclic aromatic ring, heteroaromatic ring, or a substituted derivative thereof;
R¹²-R¹⁴ are the same or different and are selected from the group consisting of alkyl, carbocyclic aryl, heteroaryl, and substituted derivatives thereof;
a, a1, b, and b1 are the same or different and are an integer from 0-3; and
c and d are the same or different and are an integer from 0-2.

All of the above-described embodiments for Q¹ in Core A, apply equally to Q¹ and Q² in Formula IX.

All of the above-described embodiments for R¹ in Formula I, apply equally to R¹, R², R⁶, R⁷, R⁹, and R¹⁰ in Formula IX.

All of the above-described embodiments for R¹²-R¹⁴ in Core A, apply equally to R¹²-R¹⁴ in Formula IX.

All of the above-described embodiments for a, a1, b, and b1 in Formula IV, apply equally to a, a1, b, and b1 in Formula IX.

All of the above-described embodiments for c and d in Formula I, apply equally to c and d in Formula IX.

Any of the above embodiments of Formula IX can be combined with one or more of the other embodiments, so long as they are not mutually exclusive.

The compounds of Formula IX can be made using any technique that will yield a C—C, C—N, C—B, or N—B bond, as described above.

Deuterated compounds can be prepared as described above.

In some embodiments, the polycyclic aromatic compound described herein has Formula X

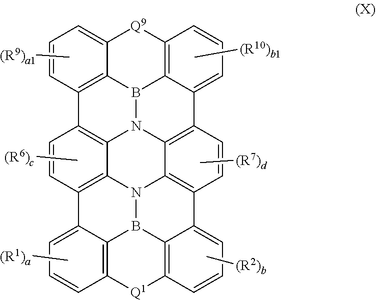

wherein:
Q¹ and Q⁹ are the same or different and are selected from the group consisting of a single bond, O, S, NR¹², BR₁₂, CR¹³R¹⁴, and SiR¹³R¹⁴; and
R¹, R², R⁶, R⁷, R⁹, and R¹⁰ are the same or different at each occurrence and are selected from the group consisting of D, F, CN, alkyl, alkoxy, fluoroalkyl, carbocyclic aryl, aryloxy, heteroaryl, diarylamino, silyl, siloxane, siloxy, germyl, deuterated alkyl, deuterated partially-fluorinated alkyl, deuterated alkoxy, deuterated carbocyclic aryl, deuterated aryloxy, deuterated heteroaryl, deuterated diarylamino, deuterated silyl, deuterated siloxane, deuterated siloxy, and deuterated germyl, where adjacent R groups or R groups on adjacent rings can be joined together to form a 5- or 6-membered cycloaliphatic ring, carbocyclic aromatic ring, heteroaromatic ring, or a substituted derivative thereof;
R¹²-R¹⁴ are the same or different and are selected from the group consisting of alkyl, carbocyclic aryl, heteroaryl, and substituted derivatives thereof;
a, a1, b, and b1 are the same or different and are an integer from 0-3; and
c and d are the same or different and are an integer from 0-2.

All of the above-described embodiments for Q¹ in Core A, apply equally to Q¹ and Q⁹ in Formula X.

All of the above-described embodiments for R¹ in Formula I, apply equally to R¹, R², R⁶, R⁷, R⁹, and R¹⁰ in Formula X.

All of the above-described embodiments for R¹²-R¹⁴ in Core A, apply equally to R¹²-R¹⁴ in Formula X.

All of the above-described embodiments for a, a1, b, and b1 in Formula IV, apply equally to a, a1, b, and b1 in Formula X.

All of the above-described embodiments for c and d in Formula I, apply equally to c and d in Formula X.

Any of the above embodiments of Formula X can be combined with one or more of the other embodiments, so long as they are not mutually exclusive.

The compounds of Formula X can be made using any technique that will yield a C—C, C—N, C—B, or N—B bond, as described above.

Deuterated compounds can be prepared as described above.

In some embodiments, the polycyclic aromatic compound described herein has Formula XI

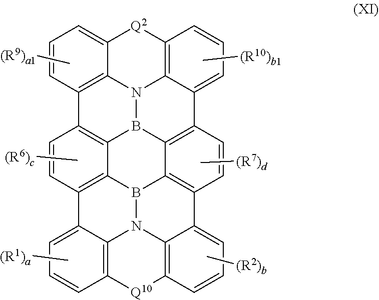

wherein:
Q² and Q¹⁰ are the same or different and are selected from the group consisting of a single bond, O, S, NR¹², BR₁₂, CR¹³R¹⁴, and SiR¹³R¹⁴; and
R¹, R², R⁶, R⁷, R⁹, and R¹⁰ are the same or different at each occurrence and are selected from the group consisting of D, F, CN, alkyl, alkoxy, fluoroalkyl, carbocyclic aryl, aryloxy, heteroaryl, diarylamino, silyl, siloxane, siloxy, germyl, deuterated alkyl, deuterated partially-fluorinated alkyl, deuterated alkoxy, deuterated carbocyclic aryl, deuterated aryloxy, deuterated heteroaryl, deuterated diarylamino, deuterated silyl, deuterated siloxane, deuterated siloxy, and deuterated germyl, where adjacent R groups or R groups on adjacent rings can be joined together to form a 5- or 6-membered cycloaliphatic ring, carbocyclic aromatic ring, heteroaromatic ring, or a substituted derivative thereof;
R¹²-R¹⁴ are the same or different and are selected from the group consisting of alkyl, carbocyclic aryl, heteroaryl, and substituted derivatives thereof;
a, a1, b, and b1 are the same or different and are an integer from 0-3; and
c and d are the same or different and are an integer from 0-2.

All of the above-described embodiments for Q¹ in Core A, apply equally to Q² and Q¹⁰ in Formula XI.

All of the above-described embodiments for R¹ in Formula I, apply equally to R¹, R², R⁶, R⁷, R⁹, and R¹⁰ in Formula XI.

All of the above-described embodiments for R¹²-R¹⁴ in Core A, apply equally to R¹²-R¹⁴ in Formula XI.

All of the above-described embodiments for a, a1, b, and b1 in Formula IV, apply equally to a, a1, b, and b1 in Formula XI.

All of the above-described embodiments for c and d in Formula I, apply equally to c and d in Formula XI.

Any of the above embodiments of Formula XI can be combined with one or more of the other embodiments, so long as they are not mutually exclusive.

The compounds having Formula XI can be made using any technique that will yield a C—C, C—N, C—B, or N—B bond, as described above. Deuterated compounds can be prepared as described above.

Examples of compounds having two B—N bonds include, but are not limited to, the compounds shown below.

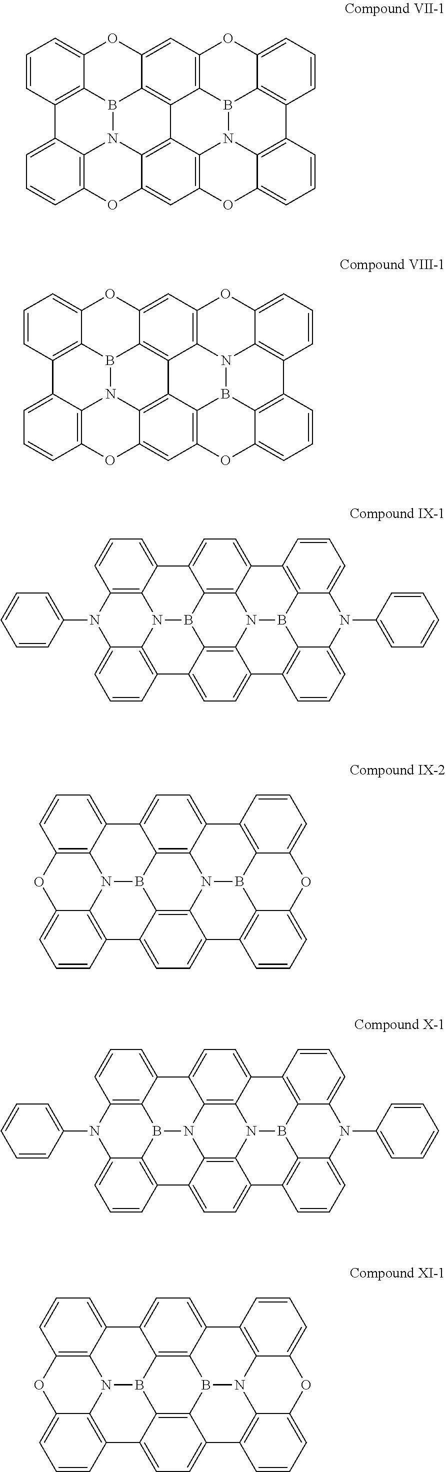

### 5. Devices

Organic electronic devices that may benefit from having one or more layers comprising the compounds described herein include, but are not limited to, (1) devices that convert electrical energy into radiation (e.g., a light-emitting diode, light emitting diode display, diode laser, or lighting panel), (2) devices that detect a signal using an electronic process (e.g., a photodetector, a photoconductive cell, a photoresistor, a photoswitch, a phototransistor, a phototube, an infrared (“IR”) detector, ora biosensors), (3) devices that convert radiation into electrical energy (e.g., a photovoltaic device or solar cell), (4) devices that convert light of one wavelength to light of a longer wavelength, (e.g., a down-converting phosphor device); (5) devices that include one or more electronic components that include one or more organic semiconductor layers (e.g., a transistor or diode), or any combination of devices in items (1) through (5).

In some embodiments, the device includes a photoactive layer having a compound as described herein.

In some embodiments, the device includes an anode and a cathode with a photoactive layer therebetween, where the photoactive layer includes a compound as described herein.

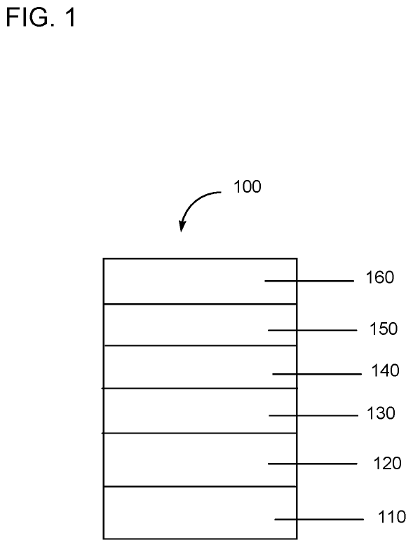

One illustration of an organic electronic device structure is shown in FIG. 1. The device 100 has a first electrical contact layer, an anode layer 110 and a second electrical contact layer, a cathode layer 160, and a photoactive layer (“EML”) 140 between them. Adjacent to the anode is a hole injection layer (“HIL”) 120. Adjacent to the hole injection layer is a hole transport layer (“HTL”) 130, comprising hole transport material.

Adjacent to the cathode may be an electron transport layer (“ETL”) 150, comprising an electron transport material. As an option, devices may use one or more additional hole injection or hole transport layers (not shown) next to the anode 110 and/or one or more additional electron injection layer (“EIL”) or electron transport layer (not shown) next to the cathode 160. As a further option, devices may have an anti-quenching layer (not shown) between the photoactive layer 140 and the electron transport layer 150.

Layers 120 through 150, and any additional layers between them, are individually and collectively referred to as the active layers.

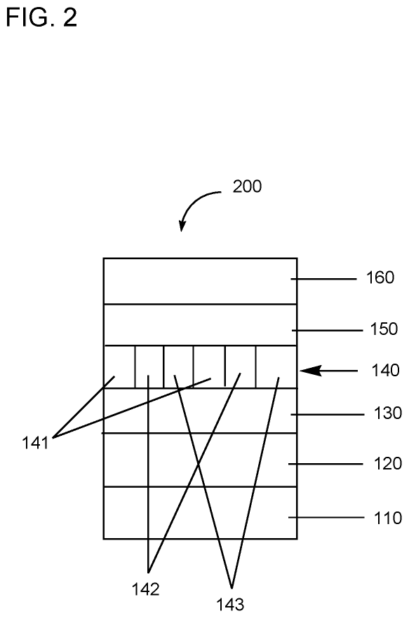

In some embodiments, the photoactive layer is pixelated, as shown in FIG. 2. In device 200, layer 140 is divided into pixel or subpixel units 141, 142, and 143 which are repeated over the layer. Each of the pixel or subpixel units represents a different color. In some embodiments, the subpixel units are for red, green, and blue. Although three subpixel units are shown in the figure, two or more than three may be used.

In some embodiments, the different layers have the following range of thicknesses: anode 110, 50-500 nm, in some embodiments, 100-200 nm; hole injection layer 120, 5-200 nm, in some embodiments, 20-100 nm; hole transport layer 130, 5-200 nm, in some embodiments, 20-100 nm; photoactive layer 140, 1-200 nm, in some embodiments, 10-100 nm; electron transport layer 150, 5-200 nm, in some embodiments, 10-100 nm; cathode 160, 20-1000 nm, in some embodiments, 30-500 nm. The location of the electron-hole recombination zone in the device, and thus the emission spectrum of the device, can be affected by the relative thickness of each layer. The desired ratio of layer thicknesses will depend on the exact nature of the materials used.

In some embodiments, the compounds described herein are useful as blue luminescent material in photoactive layer 140. They can be used alone or as a dopant in a host material.

In some embodiments, the compounds described herein have a photoluminescence emission profile with a FWHM that is less than 50 nm; in some embodiments, less than 40 nm; in some embodiments, less than 30 nm; in some embodiments, less than 20 nm. This is advantageous for display devices for producing more saturated color.

a. Photoactive Layer

As used herein, the term “compound(s) described herein” or “compound as described herein” is intended to include compounds comprising any of Core A through Core C, and include compounds having any of Formula I through Formula XI.

In some embodiments, the photoactive layer includes a host material and a compound as described herein as a dopant. In some embodiments, a second host material is present.

In some embodiments, the photoactive layer includes only a host material and a compound as described herein as a dopant. In some embodiments, minor amounts of other materials, are present so long as they do not significantly change the function of the layer.

The weight ratio of total dopant to total host material is in the range of 2:98 to 70:30; in some embodiments, 5:95 to 70:30; in some embodiments, 10:90 to 20:80.

In some embodiments, the second host material is selected from the group consisting of anthracenes, chrysenes, pyrenes, phenanthrenes, triphenylenes, phenanthrolines, naphthalenes, triazines, quinolines, isoquinolines, quinoxalines, phenylpyridines, benzodifurans, metal quinolinate complexes, indolocarbazoles, substituted derivatives thereof, and combinations thereof.

Any of the compounds described herein represented by the embodiments, specific embodiments, specific examples, and combination of embodiments discussed above can be used in the photoactive layer.

b. Other Device Layers

The other layers in the device can be made of any materials which are known to be useful in such layers.

The anode 110 is an electrode that is particularly efficient for injecting positive charge carriers. It can be made of, for example materials containing a metal, mixed metal, alloy, metal oxide or mixed-metal oxide, or it can be a conducting polymer, and mixtures thereof. Suitable metals include the Group 11 metals, the metals in Groups 4, 5, and 6, and the Group 8-10 transition metals. If the anode is to be light-transmitting, mixed-metal oxides of Groups 12, 13 and 14 metals, such as indium-tin-oxide, are generally used. The anode may also be made of an organic material such as polyaniline as described in “Flexible light-emitting diodes made from soluble conducting polymer,” Nature vol. 357, pp 477 479 (11 Jun. 1992). At least one of the anode and cathode should be at least partially transparent to allow the generated light to be observed.

The hole injection layer 120 includes hole injection material and may have one or more functions in an organic electronic device, including but not limited to, planarization of the underlying layer, charge transport and/or charge injection properties, scavenging of impurities such as oxygen or metal ions, and other aspects to facilitate or to improve the performance of the organic electronic device. The hole injection layer can be formed with polymeric materials, such as polyaniline (PANI) or polyethylenedioxythiophene (PEDOT), which are often doped with protonic acids. The protonic acids can be, for example, poly(styrenesulfonic acid), poly(2-acrylamido-2-methyl-1-propanesulfonic acid), and the like.

The hole injection layer can include charge transfer compounds, and the like, such as copper phthalocyanine, 1,4,5,8,9,12-hexaazatriphenylenehexacarbonitrile (HAT-CN), and the tetrathiafulvalene-tetracyanoquinodimethane system (TTF-TCNQ).

In some embodiments, the hole injection layer includes at least one electrically conductive polymer and at least one fluorinated acid polymer.

Examples of hole transport materials for layer 130 have been summarized for example, in Kirk-Othmer Encyclopedia of Chemical Technology, Fourth Edition, Vol. 18, p. 837-860, 1996, by Y. Wang. Both hole transporting molecules and polymers can be used. Commonly used hole transporting molecules are: N,N′-diphenyl-N,N′-bis(3-methylphenyl)-[1,1′-biphenyl]-4,4′-diamine (TPD), 1,1-bis[(di-4-tolylamino) phenyl]cyclohexane (TAPC), N,N′-bis(4-methylphenyl)-N,N′-bis(4-ethylphenyl)-[1,1′-(3,3′-dimethyl)biphenyl]-4,4′-diamine (ETPD), tetrakis-(3-methylphenyl)-N,N,N′,N′-2,5-phenylenediamine (PDA), a-phenyl-4-N,N-diphenylaminostyrene (TPS), p-(diethylamino)benzaldehyde diphenylhydrazone (DEH), triphenylamine (TPA), bis[4-(N,N-diethylamino)-2-methylphenyl](4-methylphenyl)methane (MPMP), 1-phenyl-3-[p-(diethylamino)styryl]-5-[p-(diethylamino)phenyl] pyrazoline (PPR or DEASP), 1,2-trans-bis(9H-carbazol-9-yl)cyclobutane (DCZB), N,N,N′,N′-tetrakis(4-methylphenyl)-(1,1′-biphenyl)-4,4′-diamine (TTB), N,N′-bis(naphthalen-1-yl)-N,N′-bis-(phenyl)benzidine (α-NPB), and porphyrinic compounds, such as copper phthalocyanine. In some embodiments, the hole transport layer includes a hole transport polymer. In some embodiments, the hole transport polymer is a distyrylaryl compound. In some embodiments, the aryl group has two or more fused aromatic rings. In some embodiments, the aryl group is an acene. The term “acene” as used herein refers to a hydrocarbon parent component that contains two or more ortho-fused benzene rings in a straight linear arrangement. Other commonly used hole transporting polymers are polyvinylcarbazole, (phenylmethyl)-polysilane, and polyaniline. It is also possible to obtain hole transporting polymers by doping hole transporting molecules such as those mentioned above into polymers such as polystyrene and polycarbonate. In some cases, triarylamine polymers are used, especially triarylamine-fluorene copolymers. In some cases, the polymers and copolymers are crosslinkable.

In some embodiments, the hole transport layer further includes a p-dopant. In some embodiments, the hole transport layer is doped with a p-dopant. Examples of p-dopants include, but are not limited to, tetrafluorotetracyanoquinodimethane (F4-TCNQ) and perylene-3,4,9,10-tetracarboxylic-3,4,9,10-dianhydride (PTCDA).

In some embodiments, more than one hole transport layer is present (not shown).

Examples of electron transport materials which can be used for layer 150 include, but are not limited to, metal chelated oxinoid compounds, including metal quinolate derivatives such as tris(8-hydroxyquinolato)aluminum (AlQ), bis(2-methyl-8-quinolinolato)(p-phenylphenolato) aluminum (BAlq), tetrakis-(8-hydroxyquinolato)hafnium (HfQ) and tetrakis-(8-hydroxyquinolato)zirconium (ZrQ); and azole compounds such as 2-(4-biphenylyl)-5-(4-t-butylphenyl)-1,3,4-oxadiazole (PBD), 3-(4-biphenylyl)-4-phenyl-5-(4-t-butylphenyl)-1,2,4-triazole (TAZ), and 1,3,5-tri(phenyl-2-benzimidazole)benzene (TPBI); quinoxaline derivatives such as 2,3-bis(4-fluorophenyl)quinoxaline; fluoranthene derivatives, such as 3-(4-(4-methylstyryl)phenyl-p-tolylamino)fluoranthene; phenanthrolines such as 4,7-diphenyl-1,10-phenanthroline (DPA) and 2,9-dimethyl-4,7-diphenyl-1,10-phenanthroline (DDPA); and mixtures thereof. In some embodiments, the electron transport layer further includes an n-dopant. N-dopant materials are well known. The n-dopants include, but are not limited to, Group 1 and 2 metals; Group 1 and 2 metal salts, such as LiF, CsF, and Cs₂CO₃, Group 1 and 2 metal organic compounds, such as Li quinolate; and molecular n-dopants, such as leuco dyes, metal complexes, such as W₂(hpp)₄ where hpp=1,3,4,6,7,8-hexahydro-2H-pyrimido-[1,2-a]-pyrimidine and cobaltocene, tetrathianaphthacene, bis(ethylenedithio)tetrathiafulvalene, heterocyclic radicals or diradicals, and the dimers, oligomers, polymers, dispiro compounds and polycycles of heterocyclic radical or diradicals.

In some embodiments, an anti-quenching layer may be present between the photoactive layer and the electron transport layer to prevent quenching of blue luminance by the electron transport layer. To prevent energy transfer quenching, the singlet energy of the anti-quenching material has to be higher than the singlet energy of the blue emitter. To prevent electron transfer quenching, the LUMO level of the anti-quenching material has to be shallow enough (with respect to the vacuum level) such that electron transfer between the emitter exciton and the anti-quenching material is endothermic. Furthermore, the HOMO level of the anti-quenching material has to be deep enough (with respect to the vacuum level) such that electron transfer between the emitter exciton and the anti-quenching material is endothermic. In general, anti-quenching material is a large band-gap material with high singlet and triplet energies.

The cathode 160, is an electrode that is particularly efficient for injecting electrons or negative charge carriers. The cathode can be any metal or nonmetal having a lower work function than the anode. Materials for the cathode can be selected from alkali metals of Group 1 (e.g., Li, Cs), the Group 2 (alkaline earth) metals, the Group 12 metals, including the rare earth elements and lanthanides, and the actinides. Materials such as aluminum, indium, calcium, barium, samarium and magnesium, as well as combinations, can be used.

Alkali metal-containing inorganic compounds, such as LiF, CsF, Cs₂O and Li₂O, or Li-containing organometallic compounds can also be deposited between the organic layer 150 and the cathode layer 160 to lower the operating voltage. This layer, not shown, may be referred to as an electron injection layer.

It is known to have other layers in organic electronic devices. For example, there can be a layer (not shown) between the anode 110 and hole injection layer 120 to control the amount of positive charge injected and/or to provide band-gap matching of the layers, or to function as a protective layer. Layers that are known in the art can be used, such as copper phthalocyanine, silicon oxy-nitride, fluorocarbons, silanes, or an ultra-thin layer of a metal, such as Pt. Alternatively, some or all of anode layer 110, active layers 120, 130, 140, and 150, or cathode layer 160, can be surface-treated to increase charge carrier transport efficiency. The choice of materials for each of the component layers is preferably determined by balancing the positive and negative charges in the emitter layer to provide a device with high electroluminescence efficiency.

It is understood that each functional layer can be made up of more than one layer.

c. Device Fabrication

The device layers can be formed by any deposition technique, or combinations of techniques, including vapor deposition, liquid deposition, and thermal transfer.

In some embodiments, the device is fabricated by liquid deposition of the hole injection layer, the hole transport layer, and the photoactive layer, and by vapor deposition of the anode, the electron transport layer, an electron injection layer and the cathode. Suitable liquid deposition techniques are well known in the art.

In some embodiments, all the device layers are fabricated by vapor deposition. Such techniques are well known in the art.

### EXAMPLES

The concepts described herein will be further described in the following examples, which do not limit the scope of the invention described in the claims.

### Synthesis Examples

This example illustrates the preparation of compounds having Formula I, as described above.

### Synthesis Example 1

This example illustrates the synthesis of Compound I-1.

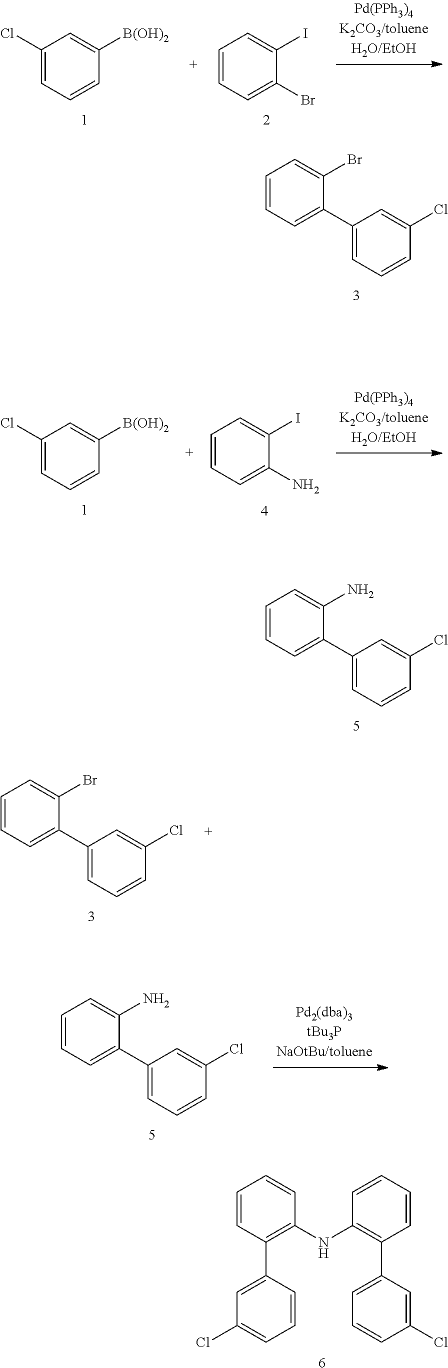

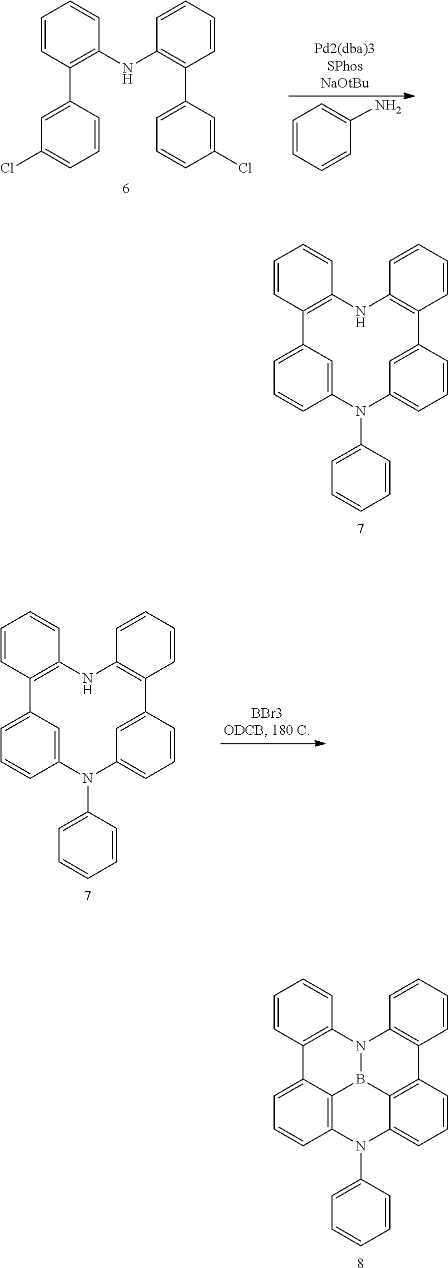

### 2-Bromo-3′-chloro-1,1′-biphenyl (3)

A mixture of 3-chlorophenylboronic acid 1 (4.7 g, 30.06 mmole), 1-bromo-2-iodobenzene 2 (8.08 g, 28.56 mmole), Pd(PPh₃)₄ (1.24 g, 1.073 mmole), potassium carbonate (9.87 g, 71.41 mmole) in toluene (100 ml), water (20 ml) and ethanol (40 ml) was degassed and stirred under nitrogen atmosphere with heating at 95° C. for 5 hours. After that the mixture was cooled down, water (100 ml) added to the mixture, organic phase separated, passed through a filter filled with silica gel eluating with toluene. The residue after evaporation of toluene in vacuum was redissolved in dichloromethane, absorbed onto celite and subjected to chromatography on silica gel column eluating with hexanes. Fractions containing product combined, eluent evaporated, the residue dried in vacuum to give 2-bromo-3′-chloro-1,1′-biphenyl 3 (3.46 g) as an oil. ¹H-NMR (CDCl₃, 500 MHz): 7.23 (td, 1H, J1=8 Hz, J2=2 Hz), 7.29-7.32 (m, 2H), 7.35-7.39 (m, 3H), 7.40-7.41 (m, 1H), 7.68 (dd, J1=8 Hz, J2=1Hz).

### 3′-Chloro-[1,1′-biphenyl]-2-amine (5)

A mixture of 3-chlorophenylboronic acid 1 (10.12 g, 64.72 mmole), 2-iodoaniline 4 (14.26 g, 63.95 mmole), Pd(PPh₃)₄ (3.05 g, 2.64 mmole), potassium carbonate (22.7 g, 164.24 mmole) in toluene (100 ml), water (20 ml) and ethanol (40 ml) was degassed and stirred under nitrogen atmosphere with heating at 95° C. for 5 hours. After that the mixture was cooled down, water (100 ml) added to the mixture, organic phase separated, passed through a filter filled with silica gel eluating with toluene. The residue after evaporation of toluene in vacuum was redissolved in dichloromethane, absorbed onto celite and subjected to chromatography on silica gel column using gradient eluation with mixtures of hexanes and dichloromethane. Fractions containing product combined, eluent evaporated, the residue dried in vacuum to give 3′-chloro-[1,1′-biphenyl]-2-amine 5 (8.88 g). ¹H-NMR (CDCl₃, 500 MHz): 3.96 (br. s, 2H), 6.79 (dd, 1H, J1=8 Hz, J2=1 Hz), 6.85 (td, 1H, J1=8 Hz, J2=1 Hz), 7.11 (dd, 1H, J1=8 Hz, J2=1 Hz), 7.19 (td, 1H, J1=8 Hz, J2=2 Hz), 7.32-7.40 (m, 3H), 7.47-7.48 (m, 1H).

### 3′-Chloro-N-(3′-chloro[1,1′-biphenyl]-2-yl)-[1,1′-biphenyl]-2-amine (6)

Reaction performed in two batches: a mixture of 2-bromo-3′-chloro-1,1′-biphenyl 3 (3.5 g totally), 3′-chloro-[1,1′-biphenyl]-2-amine 5 (2.66 g totally), tri-tert-butylphosphine (294 mg totally), Pd2(dba)3 (0.692 g totally), sodium tert-butoxide (1.55 g totally) in toluene (125 ml) was stirred under nitrogen atmosphere with heating at 40° C. for 1 hour. Combined reaction mixtures passed through a filter filled with silica gel eluating with dichloromethane. The residue after evaporation of solvents was redissolved in dichloromethane, absorbed onto celite and subjected to chromatography on silica gel column using gradient eluation with mixtures of hexanes and dichloromethane. Fractions containing product combined, eluent evaporated, the residue dried in vacuum to give 3′-chloro-N-(3′-chloro[1,1′-biphenyl]-2-yl)-[1,1′-biphenyl]-2-amine 6 (3.45 g) as viscous oil that gradually solidified upon standing. ¹H-NMR (CDCl₃, 500 MHz): 5.55 (br. s, 1H), 6.99 (td, 2H, J1=8 Hz, J2=1 Hz), 7.10 (dt, 2H, J1=8 Hz, J2=1 Hz), 7.18 (dd, 2H, J1=8 Hz, J2=1 Hz), 7.22-7.30 (m, 8H), 7.37 (dd, 2H, J1=8 Hz, J2=1 Hz).

### 10-Phenyl-10H,20H-5,9:11,15-dimethenodibenzo[b,o][1,9] diazacyclohexadecine (7)

A mixture of 3′-chloro-N-(3′-chloro[1,1′-biphenyl]-2-yl)-[1,1′-biphenyl]-2-amine 6 (0.332 g, 0.851 mmole), aniline (85 mg, 0.91 mmole), SPhos (294 mg totally), Pd2(dba)3 (35 mg, 0.085 mmole), sodium tert-butoxide (164 mg, 1.7 mmole) in toluene (25 ml) was stirred under nitrogen atmosphere with heating at 110° C. for 3 hours. Reaction mixture cooled down, toluene evaporated in vacuum, the residue was redissolved in dichloromethane, absorbed onto celite and subjected to chromatography on silica gel column using gradient eluation with mixtures of hexanes and dichloromethane. Fractions containing product combined, eluent evaporated, the residue dried in vacuum to give 10-phenyl-10H,20H-5,9:11,15-dimethenodibenzo[b,o][1,9]diazacyclohexadecine 7 (121 mg) as white solids. ¹H-NMR (CDCl₃, 500 MHz): 6.94 (td, 2H, J1=8 Hz, J2=1 Hz), 6.98 (d, 2H, J=8 Hz), 7.10 (t, 1H, J=8 Hz), 7.16-7.25 (m, 6H), 7.33-7.43 (m, 10H), 7.58 (br. s, 1H).

### Compound I-1 (8).

A mixture of compound 7 (121 mg, 0.295 mmole), 1M solution of boron tribromide in dichloromethane (1.5 ml, 1.47 mmole) in 1,2-dichlorobenzene (10 ml) was stirred under nitrogen atmosphere at 180° C. for 105 minutes. After that additional amount of 1M solution of boron tribromide in dichloromethane (0.4 ml) was added and the mixture heated at 180° C. for 2 hours. Reaction mixture cooled down, solvents evaporated suing rotary evaporator, the residue redissolved in dichloromethane, absorbed onto celite, subjected to chromatography on silica gel column using gradient eluation with mixtures of hexanes and dichloromethane. Fractions containing product combined, eluent evaporated to volume approx. 7 ml, precipitate collected by filtration to give 40 mg of Compound I-1. Filtrate was evaporated further to give 52 mg of crude product with lower purity. MS: MH+=419. ¹H-NMR (CDCl₃, 500 MHz): 6.53 (d, 2H, J=9 Hz), 7.37 (td, 2H, J1=7 Hz, J2=2 Hz), 7.42 (d, 2H, J=7), 7.48 (td, 2H, J1=8 Hz, J2=2 Hz), 7.58-7.63 (m 3H), 7.72 (t, 2H, J=8 Hz), 7.92 (d, 2H, J=8 Hz), 8.46 (dd, 2H, J1=8 Hz, J2=1 Hz), 8.51 (d, 2H, J=8 Hz). UV-vis (acetonitrile-water) λₘₐₓ (nm): 402, 384, 362, 260. Photoluminescence (toluene): 404 nm, quantum yield—76%.

This example illustrates the preparation of compounds having Formula V, as described above.

### Synthesis Example 2

This example illustrates the synthesis of Compound V-4.

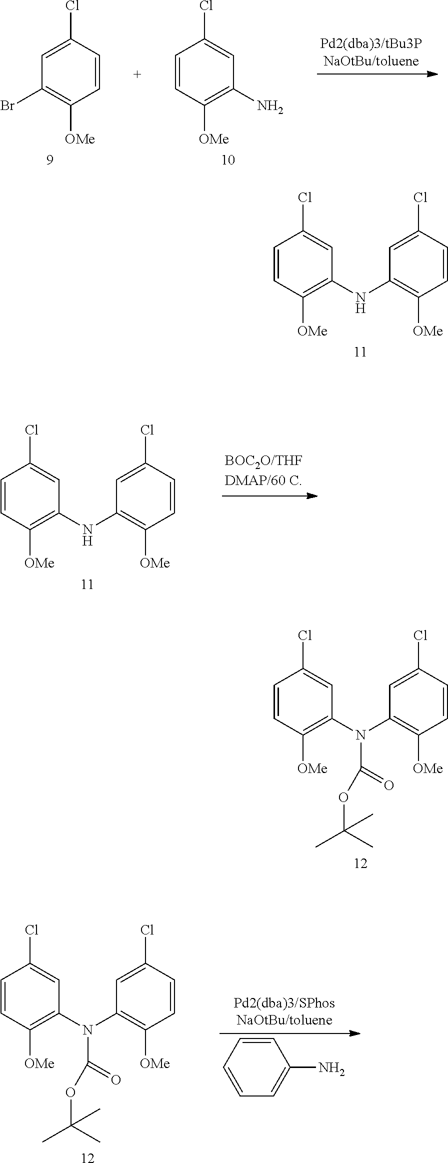

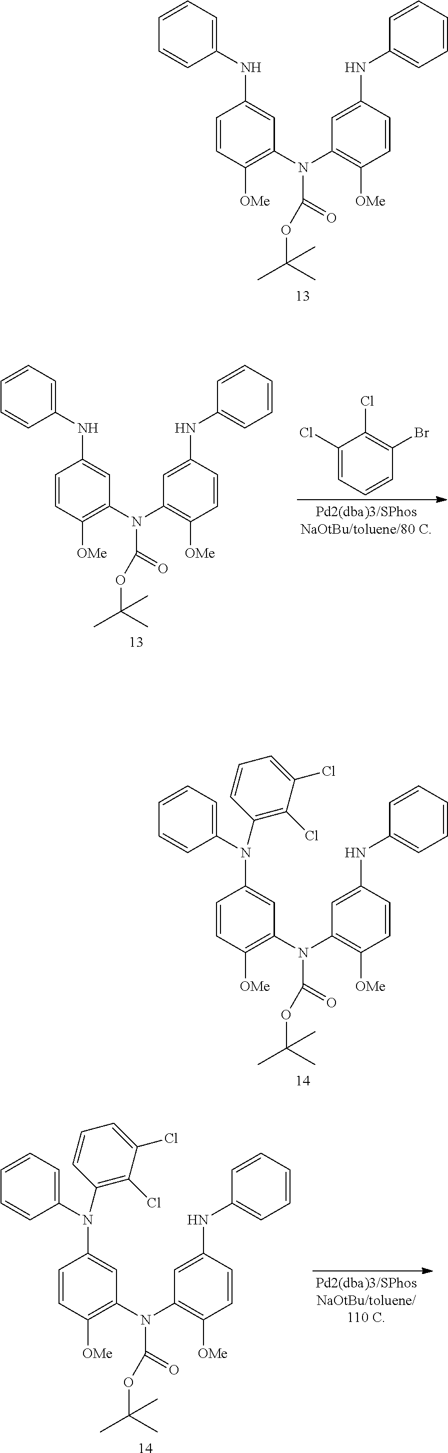

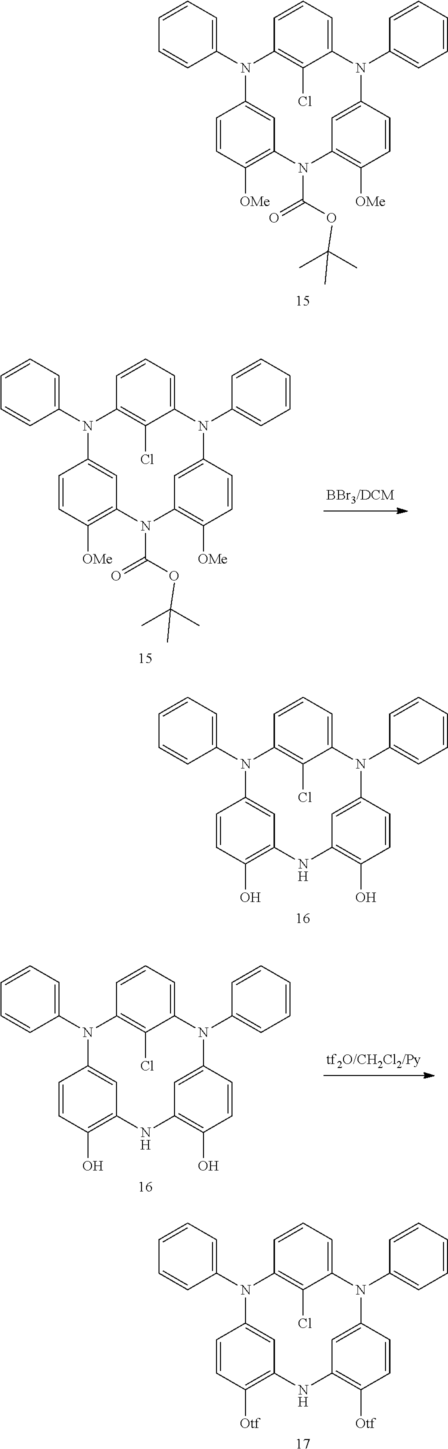

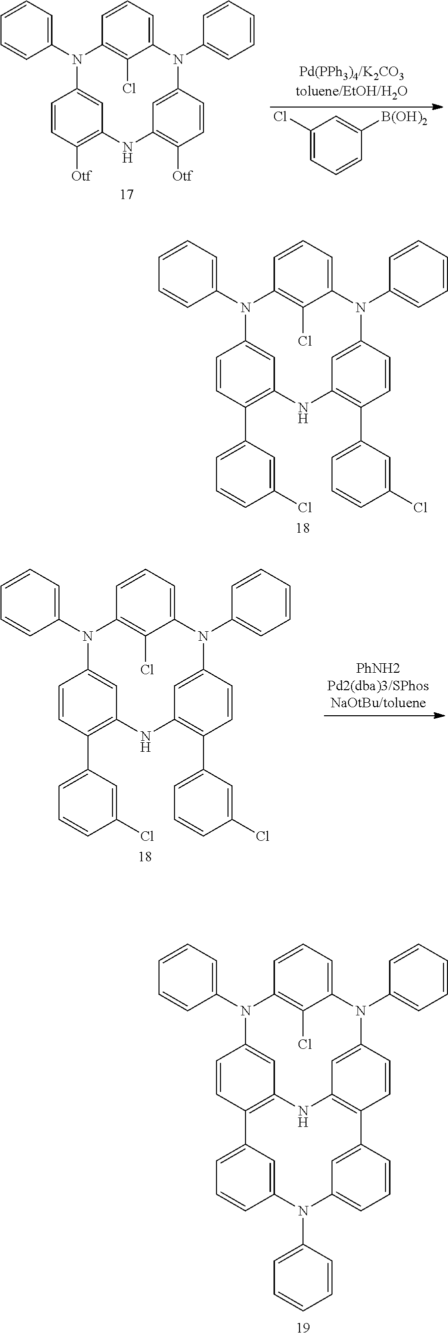

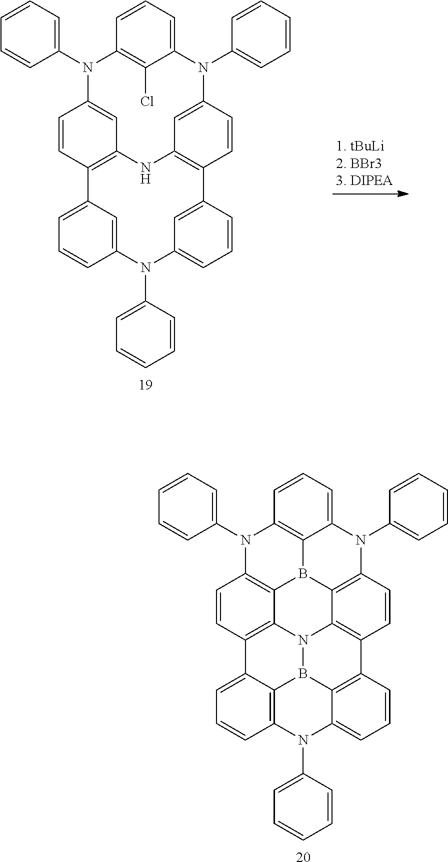

### Bis(2-bromo-5-methoxyphenyl)amine (11)

A mixture of 4-chloro-2-bromoanisole 9 (35.906 g, 162 mmole), 5-chloro-2-methoxyaniline 10 (25.55 g, 162 mmole), tri-tert-butylphosphine (0.731 g, 3.612 mmole), Pd2(dba)3 (1.654 g, 1.806 mmole), sodium tert-butoxide (18.69 g, 194.5 mmole) in toluene (100 ml) was stirred under nitrogen atmosphere at ambient temperature for 16 hours. After that the mixture diluted with methanol (150 ml), precipitate filtered, washed with methanol, water, methanol, dried in vacuum to give bis(2-bromo-5-methoxyphenyl)amine 11 (34.3 g). ¹H-NMR (CD₂C1₂, 500 MHz): 3.86 (s, 6H), 6.53 (br. s, 1 H), 6.80-6.85 (m, 4H), 7.25 (d, 2H, J=2 Hz).

### N-Tert-butoxycarbonyl-bis(2-bromo-5-methoxyphenyl)amine (12)

A mixture of bis(2-bromo-5-methoxyphenyl)amine 11 (40 g, 134 mmole), BOC₂O (100 g), DMAP (approx 1 g) in tetrahydrofuran (600 ml) was stirred under nitrogen atmosphere with heating at 57° C. for 2.5 days. After that additional amount of DMAP (0.75 g totally) and BOC₂O (98 g) added and the mixture further heated at 57° C. with stirring for another 11 hours. Reaction mixture filtered, filtrate evaporated to volume approx. 200 ml, treated with hexanes (400 ml). Precipitate collected by filtration, dried to give N-tert-butoxycarbonyl-bis(2-bromo-5-methoxyphenyl)amine 12 (41.9 g). ¹H-NMR (CD₂Cl₂, 500 MHz): 1.36 (s, 9H), 3.85 (s, 6H), 6.87 (d, 2H, J=9 Hz), 7.14 (br. s, 2H), 7.17 (dd, 2H, J1=9 Hz, J2=3 Hz).

### Compound (13).

A mixture of N-tert-butoxycarbonyl-bis(2-bromo-5-methoxyphenyl)amine 12 (41.9 g, 105.05 mmole), aniline (22.5 g, 242 mmole), SPhos (0.863 g, 2.101 mmole), Pd2(dba)3 (0.947 g, 1.034 mmole), sodium tert-butoxide (24 g, 250 mmole) in toluene (400 ml) was stirred under nitrogen atmosphere with heating at 110° C. for 3.5 hours.

Reaction mixture cooled down, filtered, precipitate washed with toluene, water, methanol, hexanes, dried to give compound 13 (48.3 g). ¹H-NMR (CD₂Cl₂, 500 MHz): 1.38 (s, 9H), 3.80 (s, 6H), 5.58 (br. s, 2H), 6.79 (t, 2H, J=7 Hz), 6.86 (d, 6H, J=9 Hz), 6.97 (d, 2H, J=9 Hz), 7.04 (d, 2H, J=3 Hz), 7.16 (t, 4H, J=8 Hz).

### Compound (14).

A mixture of compound 13 (48.3 g, 94.4 mmole), 1-bromo-2,3-dichlorobenzene (21.35 g, 94.5 mmole), SPhos (1.29 g, 3.14 mmole), Pd2(dba)3 (1.44 g, 1.57 mmole), sodium tert-butoxide (22.7 g, 236.2 mmole) in toluene (800 ml) was stirred under nitrogen atmosphere with heating at 80° C. After approx 2 hours additional amount of 1-bromo-2,3-dichlorobenzene (4.7 g, 20.81 mmole) added. Progress monitored by TLC. After nearly complete consumption of starting material, reaction mixture cooled down, washed with water. Organic phase separated, toluene distilled off using rotary evaporator, the residue redissolved in dichloromethane, absorbed onto celite and subjected to chromatography on silica gel column using gradient eluation with mixtures of hexanes and ethyl acetate. After eluation of bis-coupled product, subsequent fractions of the second peak containing pure monocoupled product combined, eluent evaporated, the residue dried in vacuum to give compound 14 (18 g). ¹H-NMR (CD₂Cl₂, 500 MHz): 1.34 (s, 9H), 3.61 (s, 3H), 3.78 (s, 3H), 6.76-6.91 (m, 7H), 6.97 (br. d, 1H, J=9 Hz), 7.02 (d, 1H, J=3 Hz), 7.09-7.19 (m, 6 H), 7.32 (dd, 1H, J1=8 Hz, J2=2 Hz).

### N²-tert-butoxycarbonyl-20-chloro-8,14-diphenyl-4,18-dimethoxy-2,8,14-triazatetracyclo[13.3.1.13,7.19,13]henicosa-1(18),3,5,7(21),9(20),10,12,15(19),16-nonaene (15)

To a stirred solution of Pd₂(dba)₃ (56 mg, 0.061 mmole), SPhos (50 mg, 0.123 mmole), NaOtBu (388 mg, 4.03 mmole) in 100 ml of toluene at 110° C. was added dropwise a solution of compound 14 in 100 ml of toluene over period of 7 hours and the resulting solution heated at 110° C. for additional 6 hours. Reaction mixture passed through a filter filled with silica gel eluating with toluene, then dichloromethane-hexanes-1:1 and finally with dichloromethane to eluate the product. Eluent evaporated, the residue dried in vacuum to give compound 15 (0.99 g). ¹H-NMR (CD₂C₂, 500 MHz): 1.44 (s, 9H), 3.75 (s, 3H), 3.77 (s, 3H), 6.54 (d, 1 H, J=3 Hz), 6.62 (d, 1H, J=3 Hz), 6.68 (d, 1H, J=9 Hz), 6.72 (d, 1H, J=9 Hz), 6.94-7.03 (m, 6H), 7.15 (t, 1H, J=8 Hz), 7.28-7.30 (m, 8 H).

### N²-tert-butoxycarbonyl-20-chloro-8,14-diphenyl-4,18-dihydroxy-2,8,14-triazatetracyclo[13.3.1.13,7.19,13]henicosa-1(18),3,5,7(21),9(20),10,12,15(19),16-nonaene (16)

Boron tribromide (12.7 g, 50.64 mmole) was added to a solution of compound 15 (6.04 g, 9.74 mmole) in dichloromethane (100 ml) at ambient temperature under nitrogen atmosphere and the resulting mixture was stirred for 3 hours. After that the mixture was poured into ice, organic phase separated, washed with water (2 times). Crude product 16 after evaporation of solvents was dried and used for the next step without further purification.

### [20-chloro-8,14-diphenyl-18-(trifluoromethylsulfonyloxy)-2,8,14-triazatetracyclo[13.3.1.13,7.19,13]henicosa-1(18),3,5,7(21),9(20),10,12,15(19),16-nonaen-4-yl] trifluoromethanesulfonate (17)

A mixture of crude compound 16 (4.79 g, 9.74 mmole), trifluoromethanesulfonic anhydride (7.69 g, 27.27 mmole), pyridine (3.85 g) in dichloromethane (100 ml) was stirred under nitrogen atmosphere cooling with water/ice bath for 3 hours. After that solvents were evaporated using rotary evaporator, the residue redissolved in a mixture of hexanes and dichloromethane (2:1), passed through short silica gel column eluating with a mixture of hexanes and dichloromethane (2:1). Eluent evaporated, the residue dried to give crude compound 17 (1.552 g) that was used for the next step without further purification. MS: MH+=756.

### N²-tert-butoxycarbonyl-20-chloro-8,14-diphenyl-4,18-bis(3-chlorophenyl)-2,8,14-triazatetracyclo[13.3.1.13,7.19,13]henicosa-1(18),3,5,7(21),9(20),10,12,15(19),16-nonaene (18)

A mixture of 3-chlorophenylboronic acid 1 (0.93 g, 5.95 mmole), the above compound 17 (1.552 g, crude), Pd(PPh₃)₄ (0.687 g, 0.595 mmole), potassium carbonate (1.37 g, 9.9 mmole) in toluene (100 ml), water (20 ml) and ethanol (40 ml) was degassed and stirred under nitrogen atmosphere with heating at 95° C. for 2 hours. After that the mixture was cooled down, water added to the mixture, organic phase separated. The residue after evaporation of toluene was redissolved in dichloromethane, absorbed onto celite and subjected to chromatography on silica gel column using gradient eluation with mixtures of hexanes and dichloromethane. Fractions containing product combined, eluent evaporated, the residue dried in vacuum to give compound 18 (0.54 g). ¹H-NMR (CD₂Cl₂, 500 MHz): 6.33 (s, 1H), 6.74 (d, 2H, J=2 Hz), 6.87-6.94 (m, 4H), 7.04-7.07 (m, 6H), 7.12-7.25 (m, 7H), 7.28-7.34 (m, 8H).

### Compound (19).

A mixture of compound 18 (540 mg, 0.79 mmole), aniline (108 mg, 1.16 mmole), Pd₂(dba)₃ (36 mg, 0.04 mmole), SPhos (32 mg, 0.08 mmole), NaOtBu (290 mg, 3.017 mmole) in 100 ml of toluene was stirred at 110° C. under nitrogen atmosphere for 19 hours. After that reaction mixture cooled down, toluene distilled off using rotary evaporator, the residue redissolved in dichloromethane, absorbed onto celite, subjected to chromatography on silica gel column using gradient eluation with mixtures of hexanes and dichloromethane. Fractions containing desired product combined, eluent evaporated, dried in vacuum to give compound 19 (126 mg). MS: MH+=702. UV-vis (acetonitrile-water), λₘₐₓ (nm): 302. ¹H-NMR (CD₂Cl₂, 500 MHz): 6.33 (s, 1H), 6.74 (d, 1H, J=2 Hz), 6.87-6.94 (m, 4H), 6.98-7.36 (m, 26H), 7.67 (s, 1 H).

### Compound V-4 (20).

Compound 19 (126 mg, 0.18 mmole) was dissolved in 10 ml of tert-butyl benzene under nitrogen atmosphere followed by addition of 0.42 ml of tert-butyllithium (1.7 M solution in pentane), resulting mixture stirred at 76° C. for 30 min. After that the mixture cooled with dry ice/acetone bath followed by addition of 0.12 ml of neat BBr3 at once. The mixture stirred at ambient temperature (water bath) for approx. 10 min, followed by addition of 0.25 ml of diisopropylethylamine. The mixture was heated at 120° C. for 2 hours. Tert-butyl benzene distilled off using rotary evaporator, the residue redissolved in dichloromethane, absorbed onto celite, subjected to chromatography on silica gel column using gradient eluation with mixtures of hexanes and dichloromethane to give Compound V-4 (18 mg) that can be further purified by crystallization. MS: MH+=683. Uv-vis (acetonitrile-water), λₘₐₓ (nm): 435, 413, 365, 336, 310, 248. ¹H-NMR (CD₂Cl₂, 500 MHz): 6.26 (d, 2H, J=8 Hz), 6.50 (d, 2H, J=9 Hz), 6.76 (d, 2H, J=9 Hz), 7.30-7.37 (m, 2H), 7.48 (d, 2H, J=7 Hz), 7.55 (d, 4H, J=8 Hz), 7.60 (t, 2H, J=8 Hz), 7.64-7.69 (m, 4H), 7.74-7.79 (m, 4H), 7.95 (d, 2H, J=8 Hz), 8.69 (d, 2H, J=9 Hz). Photoluminescence (toluene): 441 nm, full width at half maximum (fwhm)=11 nm, quantum yield — 95%.

### Device Examples

### (1) Materials

NDP-9 is 1,2,3-triylidenetris(cyanomethanylylidene)tris(2,3,5,6-tetrafluorobenzonitrile)-cyclopropane
HTM-1 is a fluorene-substituted arylamine
HTM-2 is a mono-arylamino carbazole
Host-1 is a dibenzofuran-substituted mono-aryl anthracene
Dopant-1 is a boron-containing polycyclic aromatic compound with no direct boron-nitrogen bond
ET-1is a fluorene-substituted triazene
LiQ is lithium quinolate

### (2) Devices

The emissive layers were deposited by vapor deposition as detailed below. In all cases, prior to use the substrates were cleaned in detergent, rinsed with water and subsequently dried in nitrogen.

(3) Device characterization

### Device Examples 1-2

Bottom-emission devices were fabricated on patterned indium tin oxide (ITO) coated glass substrates. Cleaned substrates were loaded into a vacuum chamber. Once pressure reached 5×10⁻⁷ Torr or below, they received thermal evaporations of the hole injection materials, a first hole transport material, a second hole transport material, the photoactive and host materials, electron transport materials and electron injection material sequentially. The bottom-emission devices were thermally evaporated with

Al cathode material. The chamber was then vented, and the devices were encapsulated using a glass lid, desiccant, and UV curable epoxy. The device had the structure, in order (unless otherwise specified, all ratios are by weight and all percentages are by weight, based on the total weight of the layer):
Glass substrate
Anode: ITO (50 nm)
HIL: HTM-1: NDP-9 97:3 (10 nm)
HTL1: HTM-1 (160 nm)
HTL2: HTM-2 (10 nm)
EML: Host-1 co-deposited with dopants as shown in Table 1 (25 nm)
ETL: ET-1: LiQ 1:1 (27 nm)
EIL: LiQ (3 nm)
Cathode: Al (100 nm)

TABLE 1
Device results

| | | Conc. | V10 | CE | | |
|---|---|---|---|---|---|---|
| Dev. Ex. | Dopant | (%) | (V) | (cd/A) | CIEx | CIEy |
| Example 1 | Compound | 1 | 4.8 | 3.8 | 0.149 | 0.052 |
| | V-4 | | | | | |
| Comparative | Dopant 1 | 3 | 4.8 | 5.7 | 0.135 | 0.078 |
| 1 | | | | | | |

Conc. (%) is the weight percent of dopant in the emissive layer; V10 is the driving voltage at 10 mA/cm²; all other data at 1000 nits.
CIEx and CIEy are the x and y color coordinates according to the C.I.E. chromaticity scale (Commission Internationale de L'Eclairage, 1931); CE is the current efficiency in cd/A.

It can be seen from Table 1 that devices with the compounds of the present invention are capable of good efficiency at extremely saturated blue color. This is an important property for OLED applications requiring bottom emission device architecture and saturated blue color.

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. Further, reference to values stated in ranges include each and every value within that range.

What is claimed is:

1. A polycyclic aromatic compound having a single boron-nitrogen bond and comprising a core structure selected from the group consisting of Core A, Core B, and Core C 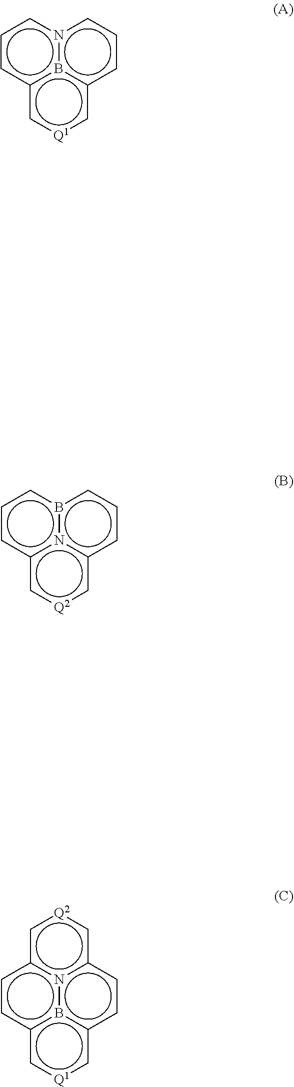
wherein:
Q¹ and Q² are the same or different and are selected from the group consisting of a single bond, O, S, NR¹², BR¹², CR¹³R¹⁴, and SiR¹³R¹⁴; and
R¹²-R¹⁴ are the same or different and are selected from the group consisting of alkyl, carbocyclic aryl, heteroaryl, and substituted derivatives thereof.

2. The compound of claim 1 having a formula selected from the group consisting of Formula I, Formula II, Formula III, Formula IV, and Formula V 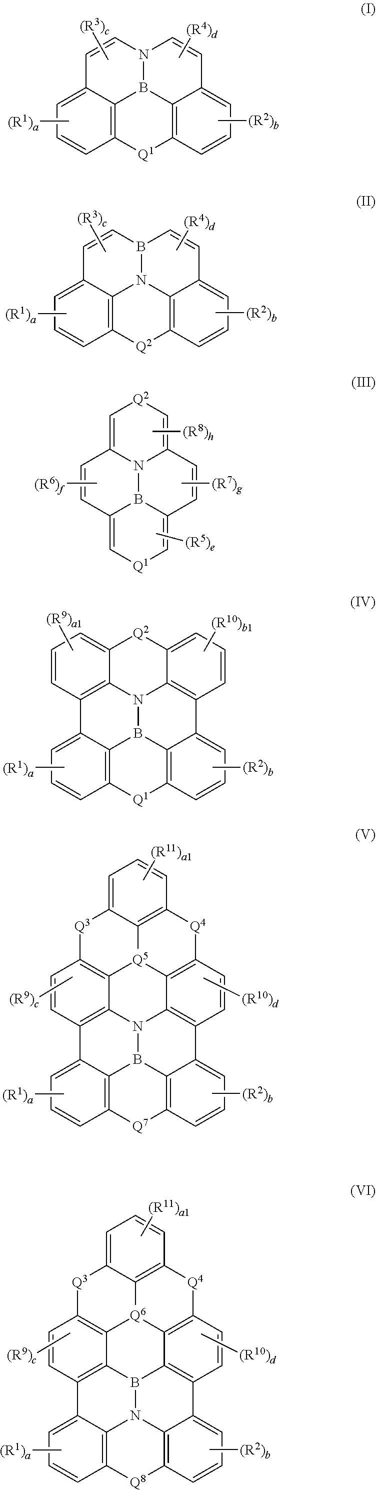
wherein:
Q¹-Q⁴ are the same or different and are selected from the group consisting of a single bond, O, S, NR¹², BR₁₂, CR¹³R¹⁴, and SiR¹³R¹⁴ ;
Q⁵ and Q⁶ are the same or different and are selected from the group consisting of N, B, P(O), CR¹³, and SiR¹³;
Q⁷ and Q⁸ are the same or different and are selected from the group consisting no bond, a single bond, O, S, NR¹², BR¹², CR¹³R¹⁴, and SiR¹³R¹⁴;
R¹-R¹¹ are the same or different at each occurrence and are selected from the group consisting of D, F, CN, alkyl, alkoxy, fluoroalkyl, carbocyclic aryl, aryloxy, heteroaryl, diarylamino, silyl, siloxane, siloxy, germyl, deuterated alkyl, deuterated partially-fluorinated alkyl, deuterated alkoxy, deuterated carbocyclic aryl, deuterated aryloxy, deuterated heteroaryl, deuterated diarylamino, deuterated silyl, deuterated siloxane, deuterated siloxy, and deuterated germyl, where adjacent R groups or R groups on adjacent rings can be joined together to form a 5- or 6-membered cycloaliphatic ring, carbocyclic aromatic ring, heteroaromatic ring, or a substituted derivative thereof;
R¹²-R¹⁴ are the same or different and are selected from the group consisting of alkyl, carbocyclic aryl, heteroaryl, and substituted derivatives thereof;
a, a1, b, and b1 are the same or different and are an integer from 0-3; and
c, d, and e-h are the same or different and are an integer from 0-2.

3. A polycyclic aromatic compound having two boron-nitrogen bonds and having a formula selected from the group consisting of Formula VII, Formula VIII, Formula IX, Formula X, and Formula XI 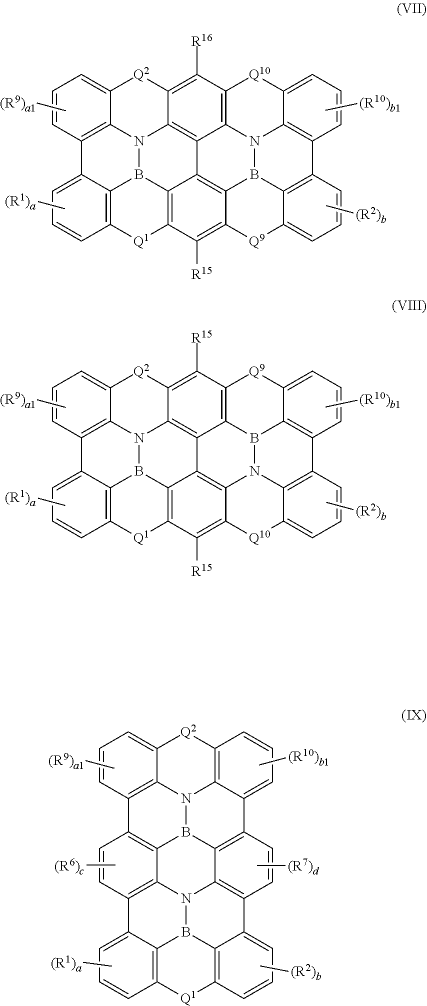 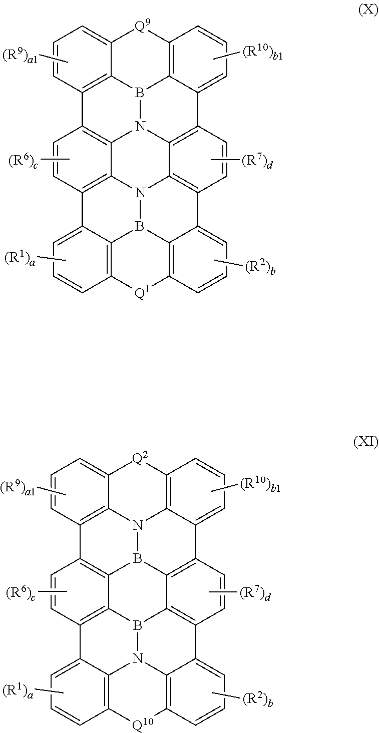
wherein:
Q¹, Q², Q⁹, and Q¹⁰ are the same or different and are selected from the group consisting of a single bond, O, S, NR¹², BR¹², CR¹³R¹⁴, and SiR¹³R¹⁴;
R¹, R², R⁶, R⁷, R⁹, and R¹⁰ are the same or different at each occurrence and are selected from the group consisting of D, F, CN, alkyl, alkoxy, fluoroalkyl, carbocyclic aryl, aryloxy, heteroaryl, diarylamino, silyl, siloxane, siloxy, germyl, deuterated alkyl, deuterated partially-fluorinated alkyl, deuterated alkoxy, deuterated carbocyclic aryl, deuterated aryloxy, deuterated heteroaryl, deuterated diarylamino, deuterated silyl, deuterated siloxane, deuterated siloxy, and deuterated germyl, where adjacent R groups or R groups on adjacent rings can be joined together to form a 5- or 6-membered cycloaliphatic ring, carbocyclic aromatic ring, heteroaromatic ring, or a substituted derivative thereof;
R¹²-R¹⁴ are the same or different and are selected from the group consisting of alkyl, carbocyclic aryl, heteroaryl, and substituted derivatives thereof;
R¹⁵ and R¹⁶ are the same or different at each occurrence and are selected from the group consisting of H, D, F, CN, alkyl, alkoxy, fluoroalkyl, carbocyclic aryl, aryloxy, heteroaryl, diarylamino, silyl, siloxane, siloxy, germyl, deuterated alkyl, deuterated partially-fluorinated alkyl, deuterated alkoxy, deuterated carbocyclic aryl, deuterated aryloxy, deuterated heteroaryl, deuterated diarylamino, deuterated silyl, deuterated siloxane, deuterated siloxy, and deuterated germyl, where adjacent R groups or R groups on adjacent rings can be joined together to form a 5- or 6-membered cycloaliphatic ring, carbocyclic aromatic ring, heteroaromatic ring, or a substituted derivative thereof;
a, a1, b, and b1 are the same or different and are an integer from 0-3; and
c and d are the same or different and are an integer from 0-2.

4. An organic electronic device comprising a first electrical contact, a second electrical contact and a photoactive layer therebetween, the photoactive layer comprising a compound according to claim 2.

5. An organic electronic device comprising a first electrical contact, a second electrical contact and a photoactive layer therebetween, the photoactive layer comprising a compound having a core structure according to claim 3.
